(19) United States
(12) Patent Application Publication
(10) Pub. No.: US 2019/0131188 A1
(43) Pub. Date: May 2, 2019

(54) Integrated Process Flow For Semiconductor Devices

(71) Applicant: The Charles Stark Draper Laboratory, Inc., Cambridge, MA (US)

(72) Inventors: Jordan Chesin, Cambridge, MA (US); Winston Chern, Cambridge, MA (US); Richard H. Morrison, JR., Taunton, MA (US); John M. Muza, Venetia, PA (US)

(21) Appl. No.: 16/178,127

(22) Filed: Nov. 1, 2018

Related U.S. Application Data
(60) Provisional application No. 62/580,379, filed on Nov. 1, 2017.

(51) Int. Cl. H01L 21/84; H01L 27/12

(52) U.S. Cl. CPC H01L 21/84; H01L 21/3212; H01L 27/1203

(57) ABSTRACT

A method of fabricating a semiconductor device comprises forming, within a single process flow on a silicon on insulator (SOI) wafer, at least one of an n channel, digital VeSFET, a p channel, digital VeSFET, an n channel, analog VeSFET and a p channel, analog VeSFET. The method may further comprise forming, on the SOI wafer, at least one of a JFET, a BJT and a LT-MOM capacitor. The method may further comprise forming the n channel, digital VeSFET, a p channel, digital VeSFET, an n channel, analog VeSFET, and a p channel, analog VeSFET, according to a periodic design based on a unit circle. The method may comprise modifying a design of the semiconductor node, according to a three-dimensional architecture, to form a modified semiconductor node, and fabricating the modified semiconductor node on substrate, along with at least one other node of a different node type.

### RELATED APPLICATIONS

This application claims the benefit of U.S. Provisional Application No. 62/580,379, filed on Nov. 1, 2017. This application is related to U.S. Provisional Application No. 62/466,673, filed on Mar. 3, 2017, and to U.S. Provisional Application No. 62/850,401, filed on Nov. 1, 2017. The entire teachings of the above applications are incorporated herein by reference.

### BACKGROUND

Existing semiconductor process flows do not facilitate the integration of Field Effect Transistors (FETs), Junction Field Effect Transistors (JFETs) and Bipolar Junction Transistors (BJTs). Traditional processes to fabricate the above-mentioned devices have certain aspects and characteristics that may be inconsistent and/or incompatible with aspects and characteristics of the other devices. One example is that bipolar junction transistors tend to be formed as a vertically-oriented device, rather than laterally-oriented as is true for field effect transistors. These inconsistencies and incompatibilities may conflict within a process flow, such that conventional fabrication philosophies separate the fabrication of the different devices into individual process flows.

### SUMMARY

The described embodiments are directed to an electrical device integration solution that may be used to fabricate three fundamental transistor types, e.g., Vertical Slit Field Effect Transistor (VeSFET) devices, JFET devices and BJT devices, on the same underlying substrate wafer and within a single process flow.

The VeSFET may be used in a periodic design based on unit circle with through-thickness tungsten plugs for low parasitic capacitances and resistance with dense packing. Such a design may result in higher performance for a given node, are inherently resistant to ionizing radiation, exhibit a high I_{ON}/I_{OFF} characteristics and low power consumption.

The described embodiments may be used to produce an integration of complementary VeSFETs for high speed/bandwidth VeSFETs based on the unit-circle, Analog VeSFETs (AVeSFETs) designed for analog performance, JFETs and BJTs, along with high capacitance-density lateral thermalmetal-oxide-metal (LT-MOM) capacitors.

An example embodiment of the integration and fabrication process of the invention is summarized in FIGS. 1A, 1B, 1C and 1D. Although certain parameters (e.g., layer thickness) are specified for this example embodiment, and for other example embodiments throughout this description, such specifications are meant to be explanatory and are not meant to be limiting.

Referring to FIG. 1A, the example process starts with a silicon on insulator (SOI) wafer with a silicon thickness of 50 nm to 250 nm, and a buried oxide thickness of 150 nm to 1000 nm. Four implant steps are performed in succession to create doped semiconductor regions for the fabrication of n and p channel VeSFETs, both circular (e.g., high speed/bandwidth) and analog; n and p channel JFETs; and the collector and base of npn and pnp transistors.

Referring to FIG. 1B, subsequent steps form the channel and gate of VeSFETs, the channels of the JFETs, and the sacrificial emitters of the npn and pnp BJTs.

FIG. 1C illustrates the result of polysilicon replacement of the n-type VeSFET, and FIG. 1D shows the result of an epitaxial process that is used to create the gates for n and p channel JFET, and the emitter polysilicon replacement of the npn and pnp transistor.

FIG. 1E illustrates example devices fabricated as a result of the process steps depicted in FIGS. 1A through 1D.

The described embodiments may be used to produce integrated devices for, e.g., defense applications requiring radiation-hard monolithic interface electronics with MEMS, and commercial applications in spaces where a high level of integration is necessary, such as Internet of Things (IoT) and data storage (e.g., non-volatile memory in the form of VeSFET-based flash memory).

The described embodiments present a process flow that facilitates the design and build of a mixed circuit system on a wafer, and due to the unique nature of the devices, the control of circuit parameters by physical device shape and standard process deviations to control circuit operation.

In one aspect, the invention may be a method of fabricating a semiconductor device, comprising, within a single process flow, forming, on a silicon on insulator (SOI) wafer, at least one of an n channel, digital VeSFET, a p channel, digital VeSFET, an n channel, analog VeSFET, and a p channel, analog VeSFET. The method may further comprise forming, on the SOI wafer, at least one of a JFET, a BJT and a LT-MOM capacitor.

The method may further comprise forming the at least one of an n channel, digital VeSFET, a p channel, digital VeSFET, an n channel, analog VeSFET, and a p channel, analog VeSFET, according to a periodic design based on a unit circle. In one embodiment, forming the at least one of an n channel, digital VeSFET, a p channel, digital VeSFET, an n channel, analog VeSFET, and a p channel, analog VeSFET, may comprise one or more of (i) defining a mesa, (ii) growing sacrificial oxide and n-VeSFET gate oxide, (iii) depositing p+ poly-Si for n-VeSFET gates, (iv) performing chemical-mechanical planarization (CMP), (v) depositing a nitride protective layer, (vi) defining an n-VeSFET gate, (vii) growing a p-VeSFET gate oxide, (viii) depositing n+ poly-Si for p-VeSFET gates, (ix) depositing a nitride protective layer, and (x) defining an p-VeSFET gate.

In an embodiment, forming the BJT may comprise one or more of (i) growing screen oxide for at least one implant, (ii) etching at least one alignment mark, (iii) doping an npn collector, (iv) doping a pnp collector, (v) doping a p-channel and npn base; (vi) doping an n-channel and pnp base, (vii) performing an activation anneal and an oxide removal, (viii) defining an npn emitter, (ix) depositing an n+ poly-Si for npn-emitter and n-contact fill, and (x) performing chemical-mechanical planarization (CMP).

In an embodiment, forming the JFET may comprise one or more of performing an oxide fill, (ii) defining an n-JFET gate and p-contact, and (iii) defining a p-JFET gate and n-contact.

In an embodiment, forming the LT-MOM capacitor may comprise one or more of (i) defining an LT-MOM capacitor, (ii) etching a poly-Si layer with XeF2, (iii) performing a chemical vapor deposition (CVD) of tungsten, and (iv) performing chemical-mechanical planarization (CMP).

In another aspect, the invention may be a method of fabricating a semiconductor device, comprising, within a single process flow, forming, on a silicon on insulator (SOI) wafer, at least one of an n channel, digital VeSFET, a p channel, digital VeSFET, an n channel, analog VeSFET, and a p channel, analog VeSFET. The method may further comprise forming, on the SOI wafer, at least one of an n channel JFET, a p channel JFET, an npn BJT, a pnp BJT, and a LT-MOM capacitor.

In another aspect, the invention may be a method of enhancing performance of a semiconductor node, comprising modifying a design of the semiconductor node, according to a three-dimensional architecture, to form a modified semiconductor node, and fabricating the modified semiconductor node on substrate, along with at least one other node of a different node type.

In another aspect, the invention may be a method of enhancing performance of semiconductor nodes, comprising modifying a design of a first semiconductor node, according to a first three-dimensional architecture, to form a first modified semiconductor node, modifying a design of a second semiconductor node, according to a second three-dimensional architecture, to form a second modified semiconductor node, and fabricating the first modified semiconductor node and the second modified semiconductor node on substrate. The first semiconductor node is a JFET, and the second semiconductor node is a MOSFET.

### BRIEF DESCRIPTION OF THE DRAWINGS

The patent or application file contains at least one drawing executed in color. Copies of this patent or patent application publication with color drawings will be provided by the Office upon request and payment of the necessary fee.

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIGS. 1A, 1B, 1C and 1D show an example embodiment of the integration and fabrication process of the invention.

FIG. 1E illustrates example devices fabricated as a result of the process steps depicted in FIGS. 1A through 1D.

FIG. 2A through FIG. 36 describe example embodiment of process flow steps according to the invention.

FIG. 37 shows a table that describes process flow complexity for integrations several combinations of device types.

FIG. 38 shows technology computer aided design (TCAD) modeled properties of the various devices.

FIG. 39 shows a comparison of the process flow of the described embodiments to other existing process flow technologies.

FIGS. 40A, 40B, 40C, and 40D illustrate example methods of semiconductor fabrication according to the embodiments.

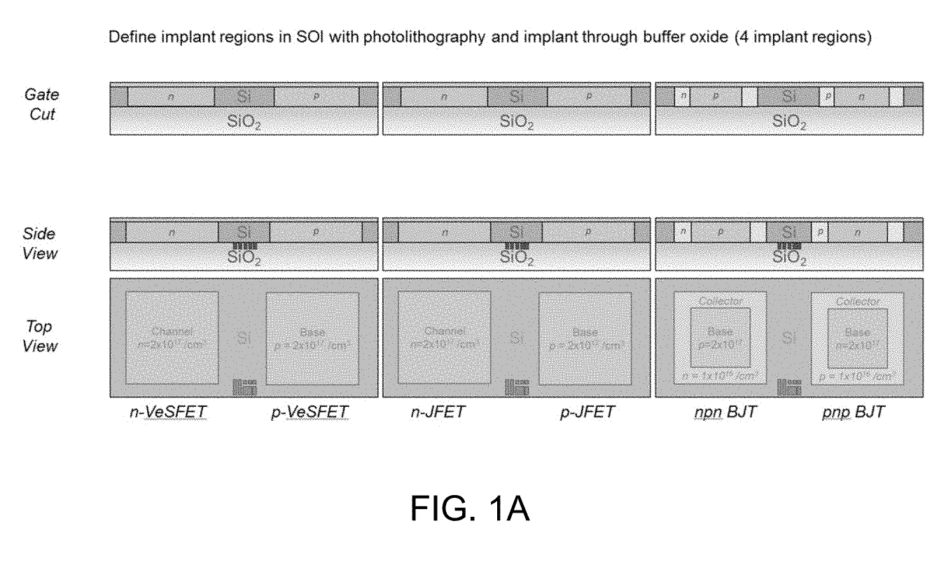

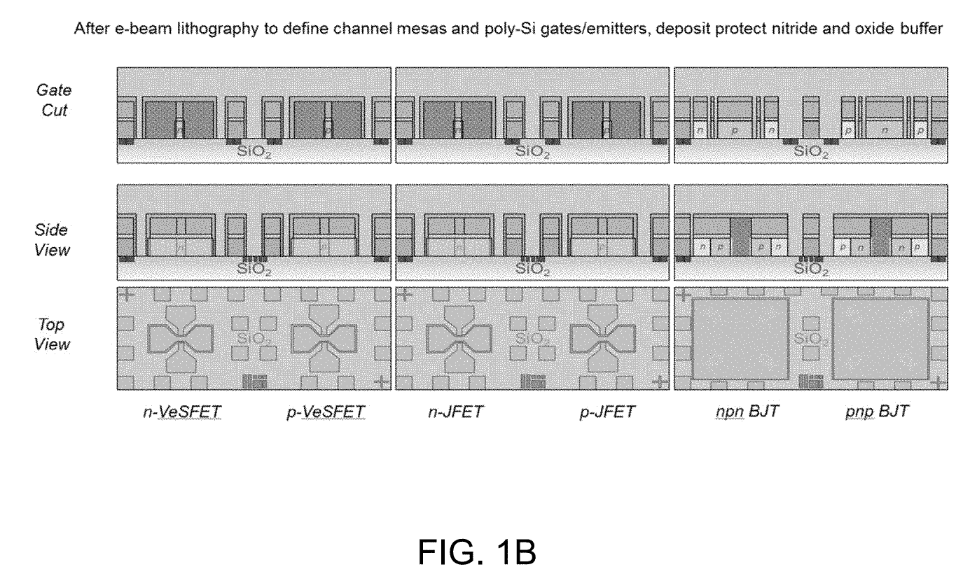

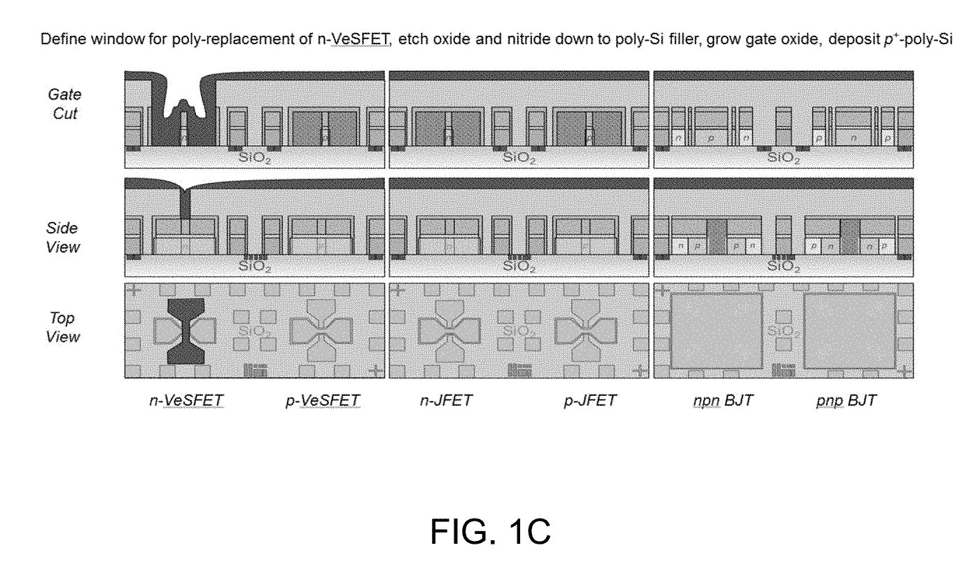

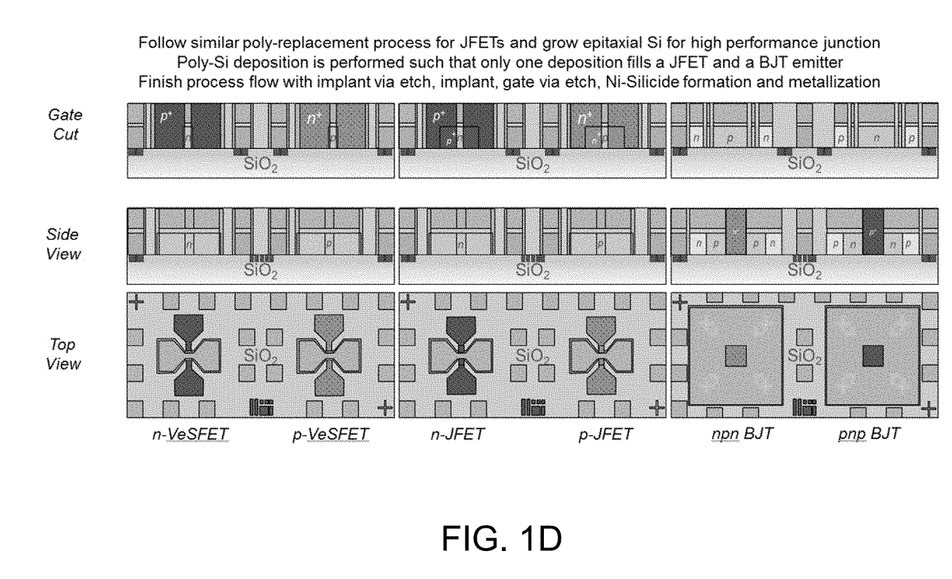

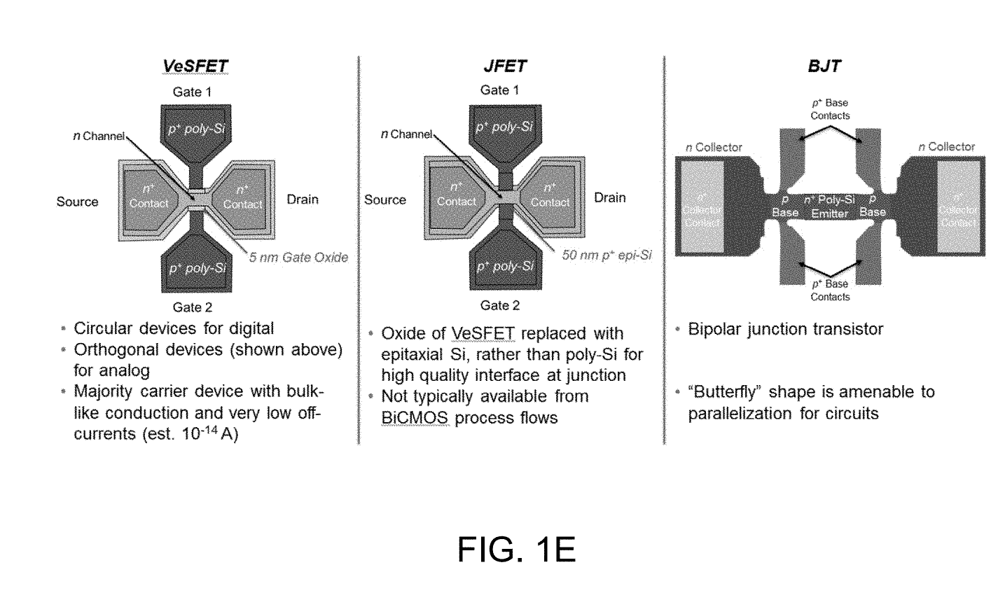

### DETAILED DESCRIPTION

A description of example embodiments follows.

The teachings of all patents, published applications and references cited herein are incorporated by reference in their entirety.

The described embodiments are directed to a process flow for the fabrication of a family of devices built on silicon-on-insulator (SOI) wafers. An SOI basis material is advantageous to build complementary metal-oxide semiconductor (CMOS) circuits, because SOI material isolates devices facilitating low off-currents, and the device isolation greatly reduces the likelihood of a latch-up occurrence. Further, devices fabricated from SOI material are inherently radiation hard (i.e., resistant to degradation due to ionizing radiation).

The process flow of the described embodiments may be used to fabricate several different families of electrical devices on the same SOI wafer, all within one process flow. The families of electrical devices may include one or more of (i) Vertical Slit Field Effect Transistor (VeSFET) both high speed/bandwidth and analog types (as described herein, a high speed/bandwidth VeSFET is simply referred to as VeSFET, and an analog VeSFET is referred to as AVeSFET), (ii) Junction Field Effect Transistor (JFET), (iii) Bipolar Junction Transistor (BJT), (iv) Lateral Thermal Metal/Oxide/Metal Capacitor (LT-MOM) and (v) a flash memory VeSFET cell (i.e., a flash memory cell based on VeSFET devices). The above-mentioned devices each have certain characteristics that may be useful in particular circuit applications. Through a process based on the process flow of the described embodiments, any combination of the above-mentioned devices can be used to define a system of interest, thereby taking advantage of the different device characteristics all on the same basis material (i.e., SOT substrate).

A VeSFET is a majority carrier device that is modulated by two gates situated on opposing sides of a silicon slit. Gate material is chosen such that the associated work function difference pinches off the channel, and application of a gate bias allows current to flow from drain to source. The digital version of the VeSFET takes advantage of the repetitive nature of the device to increase the packing density. The analog version is larger but provides other advantages. For example, the channel length for analog VeSFETs can be adjusted, which may improve the output impedance of the transistor. This is important in applications where low frequency operation is suitable, such as current sources. Current sources are intended to be DC biasing circuits (hence minimal speed concerns), but require high output impedance. The ability to adjust length allows the bias point adjustment for a given current flow. As an example, low transconductance for internal loads of amplifier designs are preferred, which may be achieved by increasing the length. The ability to adjust length allows a much larger gate area for a given current, which would improve the 1/F (Flicker) noise performance at the expense of slower speeds.

The JFET may use a defined P/N junction to modulate the transistor and may be used in circuits requiring a high input impedance. The BJT devices are built in a lateral fashion and may be used in high performance analog applications (e.g., amplifiers).

The LT-MOM uses the gate oxide of the devices to create embedded capacitors having a very high capacitance per unit area (e.g., F/cm²) for use in analog circuits.

Combinations of these devices on a single substrate, made possible by the process flow of the described embodiments, allow a designer to define and fabricate devices useful in mixed-signal circuit applications. Examples of components of such mixed-signal circuit applications may include differential amplifier with gain stages, analog to digital converters (ADCs), general digital logic components, data storage (i.e., digital storage), among others.

For an example embodiment, the major process flow steps may be summarized as follows:

| | |
|---|---|
| 1. | Start with SOI (low-level doping, 200 nm thick) |
| 2. | Grow screen oxide for implants |
| 3. | Etch alignment marks |
| 4. | Dope npn collector |
| 5. | Dope pnp collector |
| 6. | Dope p-channel and npn base |
| 7. | Dope n-channel and pnp base |
| 8. | Activation anneal and oxide removal |
| 9. | Oxide/nitride protective layer |
| 10. | Mesa definition |
| 11. | Sacrificial oxide and n-VeSFET gate oxide growth |
| 12. | p⁺ poly-Si deposition for n-VeSFET gates, CMP |
| 13. | Nitride protective layer, n-VeSFET gate definition |
| 14. | p-VeSFET gate oxide growth |
| 15. | n⁺ poly-Si deposition for p-VeSFET gates, CMP |
| 16. | Nitride protective layer, p-VeSFET gate definition |
| 17. | Oxide fill, n-JFET gate and p-contact definition |
| 18. | p⁺ epitaxial-Si growth |
| 19. | pnp-emitter definition |
| 20. | p⁺ poly-Si deposition for pnp-emitter and p-contact fill, CMP |
| 21. | p-JFET gate and n-contact definition |
| 22. | n⁺ epitaxial-Si growth |
| 23. | npn-emitter definition |
| 24. | n⁺ poly-Si deposition for npn-emitter and n-contact fill, CMP |
| 25. | LT-MOM capacitor definition and poly etch with XeF₂ |
| 26. | W CVD and CMP |
| 27. | LT-MOM capacitor definition and Si etch with XeF₂ |
| 28. | W CVD and CMP |
| 29. | Gate contact definition and oxide etch |
| 30. | S/D and BJT contact definition and poly etch |
| 31. | Silicide formation |
| 32. | W CVD and CMP |
| 33. | Metal BOEL (BJT emitter and LT-MOM capacitor is accessed) |

Details of these summary steps are set forth in more detail below.

### Process Flow Details

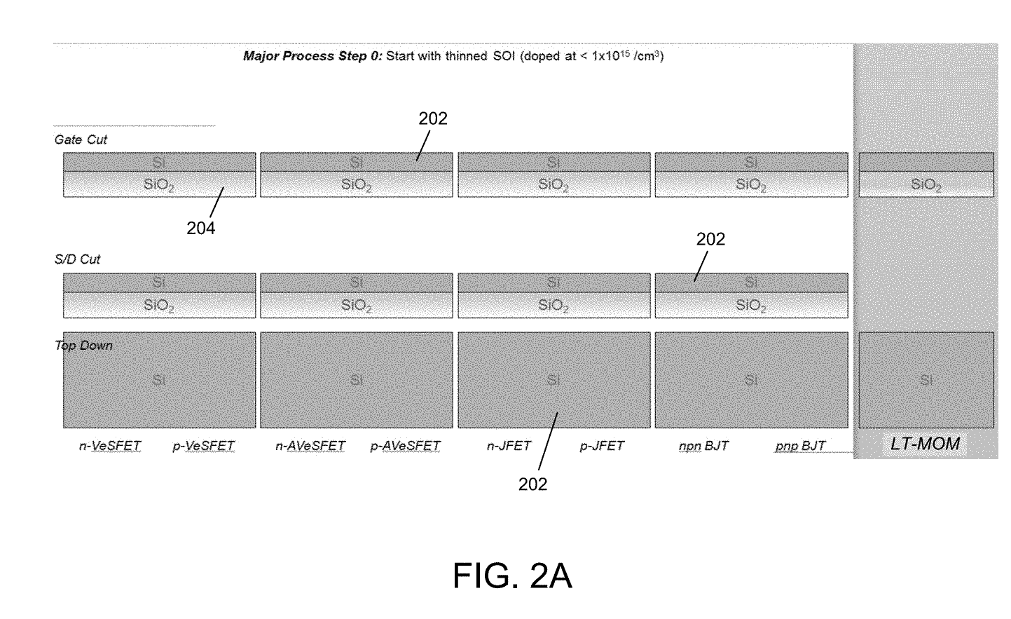

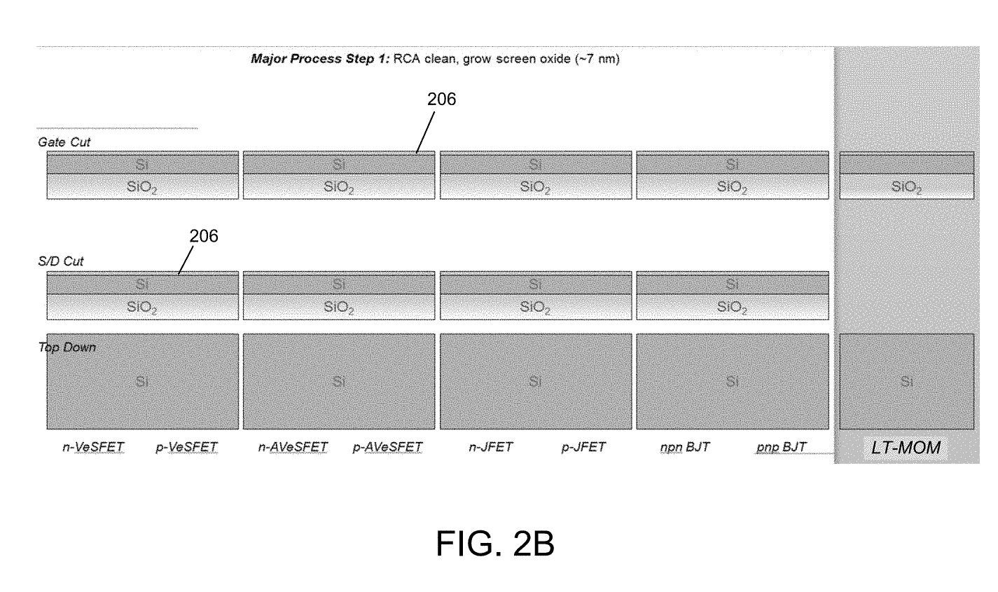

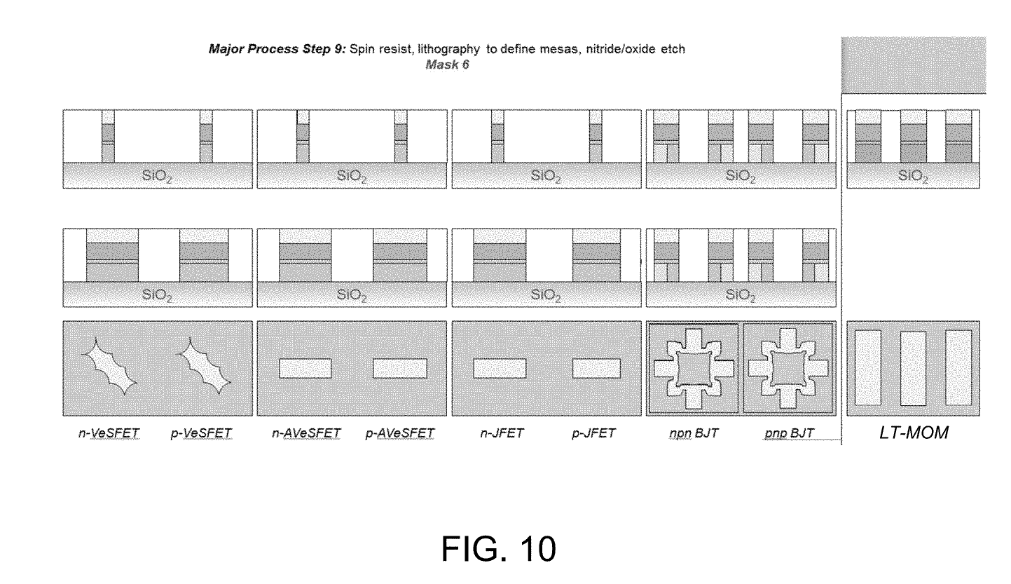

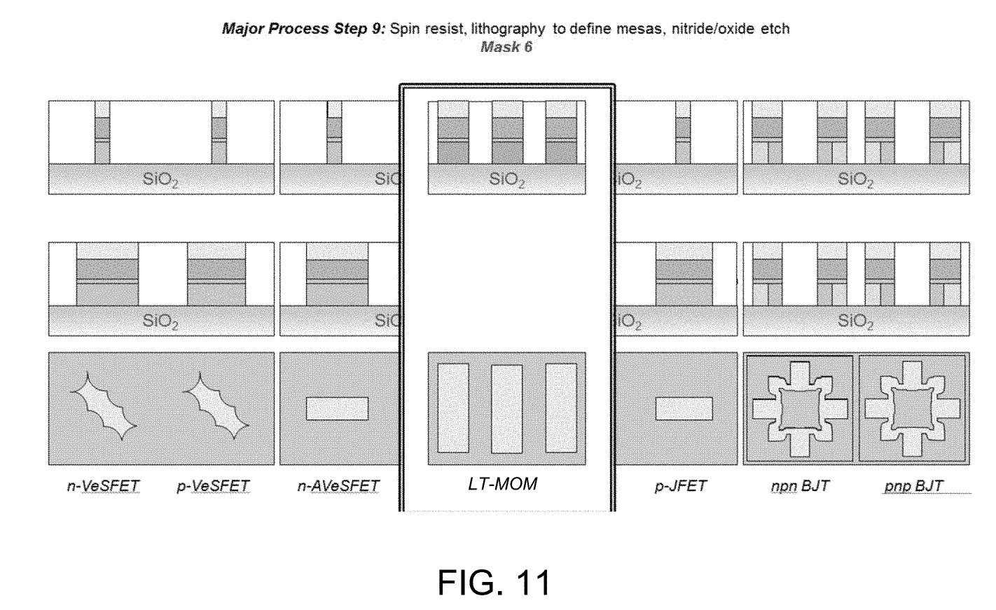

FIG. 2A through FIG. 36 describe example embodiment of process flow steps according to the invention. Each figure shows three views—a gate cut view, a source and drain (S/D) cut view, and a top-down view—from the upper portion of the figure to the lower portion of the figure. The gate cut and the S/D cut views provide orthogonal side-sectional views through the wafer. The gate cut view is through the dual gates of the VeSFET, and the S/D cut view is through the source and drain of the VeSFET. The top-down view is a view from above the device to show the top of the wafer. Several device types are shown across the figures. From left to right are shown (i) an n-type VeSFET, (ii) a p-type VeSFET, (iii) an n-type AVeSFET, (iv) a p-type AVeSFET, (v) an n-type JFET, (vi) a p-type JFET, (vii) an npn BJT, (viii) a pnp BJT, and (ix) a LT-MOM capacitor.

Referring to FIG. 2A, the starting wafer is SOI (silicon on an insulator layer of silicon dioxide) with a silicon layer that may be in the range of 50 nm to 300 nm. In this example embodiment, the silicon layer 202 may be about 200 nm thick. The silicon thickness may determine the ultimate current carrying capability, and so depends on the performance of the end product circuit (i.e., the target circuit). The buried silicon dioxide 204 (also referred to herein as the buried oxide) may be in the range of 150 nm to 1000 nm thick. As with the silicon layer 202, the thickness of the oxide layer 204 may depend on the target circuit performance. The silicon layer 202 may be doped to less than 1×10¹⁵. The dopant species does not matter.

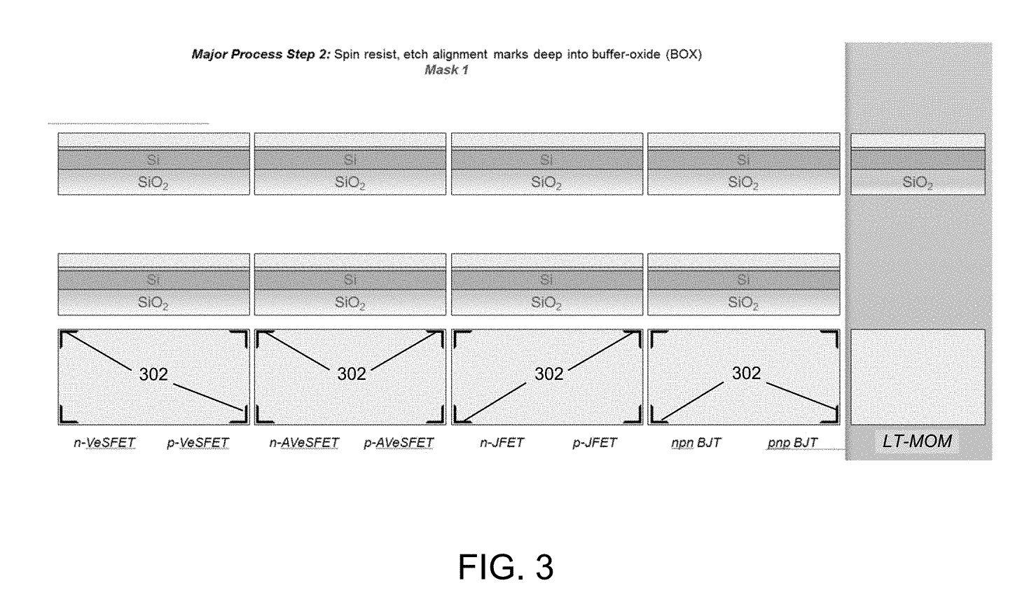

FIG. 2B shows a growth of a screen oxide 206 for implant and global alignment marks for the specific lithography tool employed. In the example embodiment, the screen oxide is approximately 7 nm, although other thicknesses may be employed. FIG. 3 shows how lithography is used to define alignment marks 302, which may be etched deep into the buffer oxide.

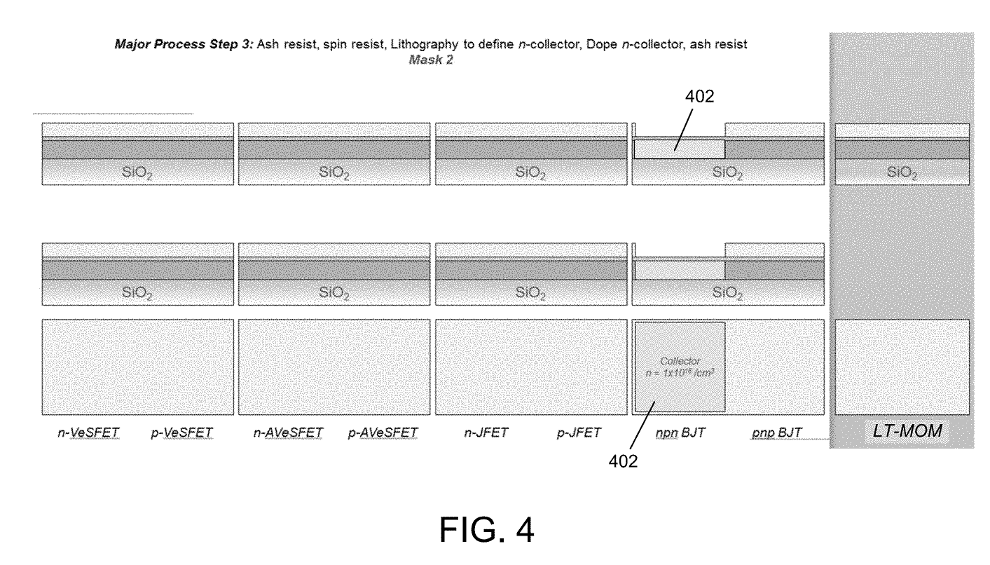

FIG. 4 shows an implant of n-type dopant 402 to create a collector tub for the BJT npn transistor. The range of the dopant concentration may depend on the characteristics of the transistor as it relates to the target circuit.

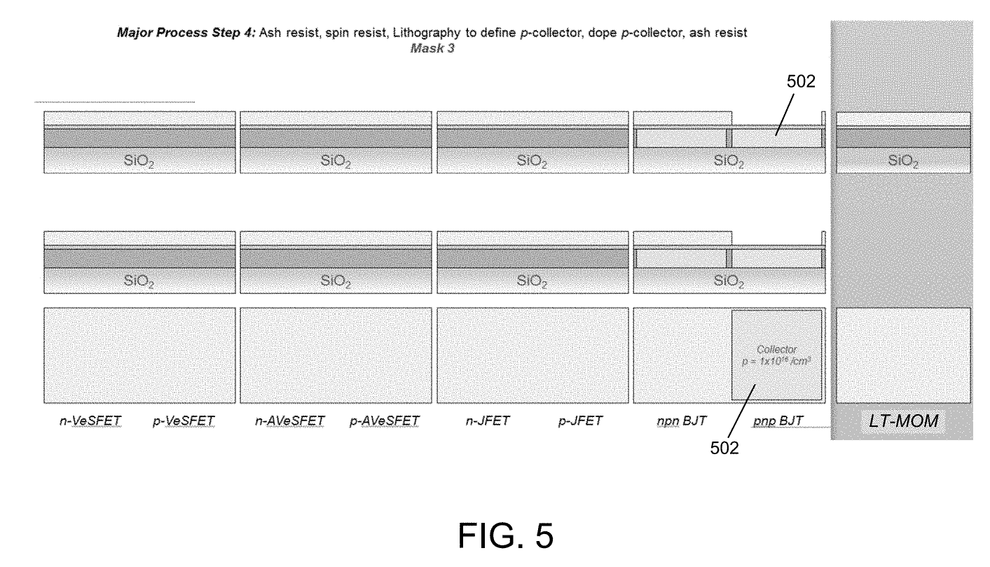

FIG. 5 shows an implant of p-type dopant 502 to define a collector tub for the BJT pnp transistor. The range of the dopant concentration may depend on the characteristics of the transistor as it relates to the target circuit.

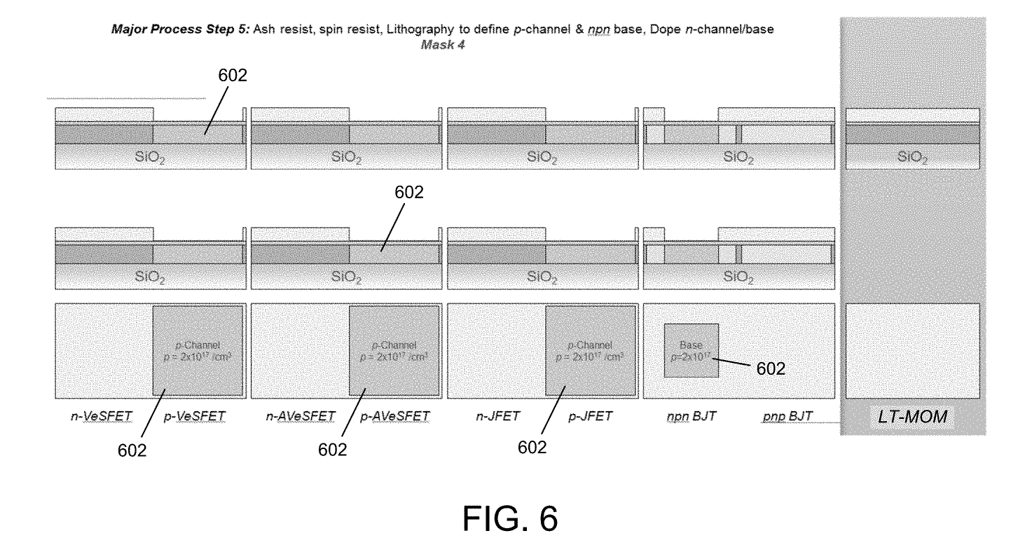

FIG. 6 shows regions of p-type dopant 602 applied to define the slit for the digital and analog VeSFETs, as well as the slit for the p-type JFET and the base of the npn BJT. The range of the dopant concentration may depend on the characteristics of the transistor as it relates to the target circuit. This can also be performed in separate steps to define separate doping levels for the individual devices.

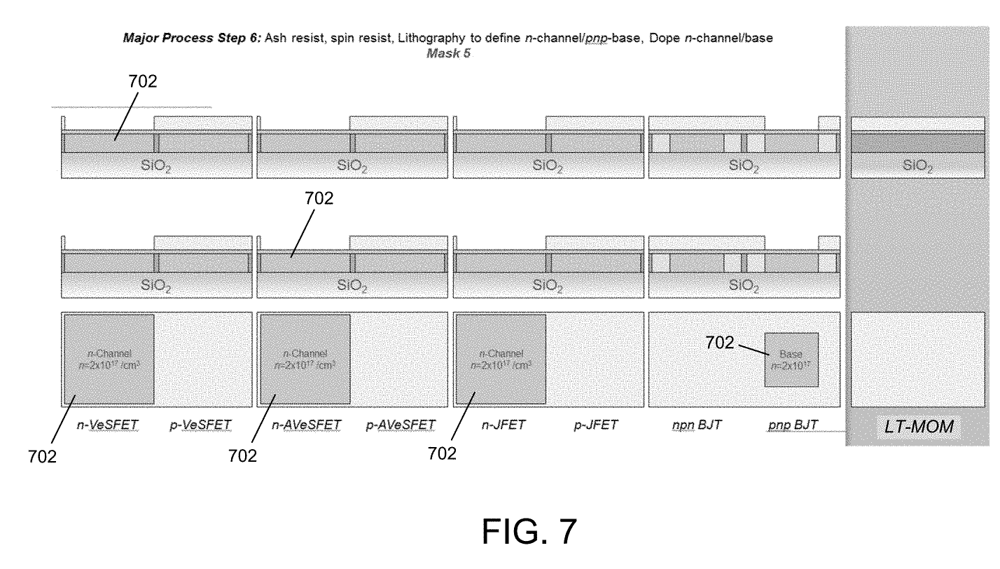

FIG. 7 shows regions of n-type dopant 702 to define the slit for the digital and analog VeSFETs, as well as the slit for the n-type JFET and the base of the pnp BJT. The range of the dopant concentration may depend on the characteristics of the transistor as it relates to the target circuit. This can also be performed in separate steps to define separate doping levels for the individual devices.

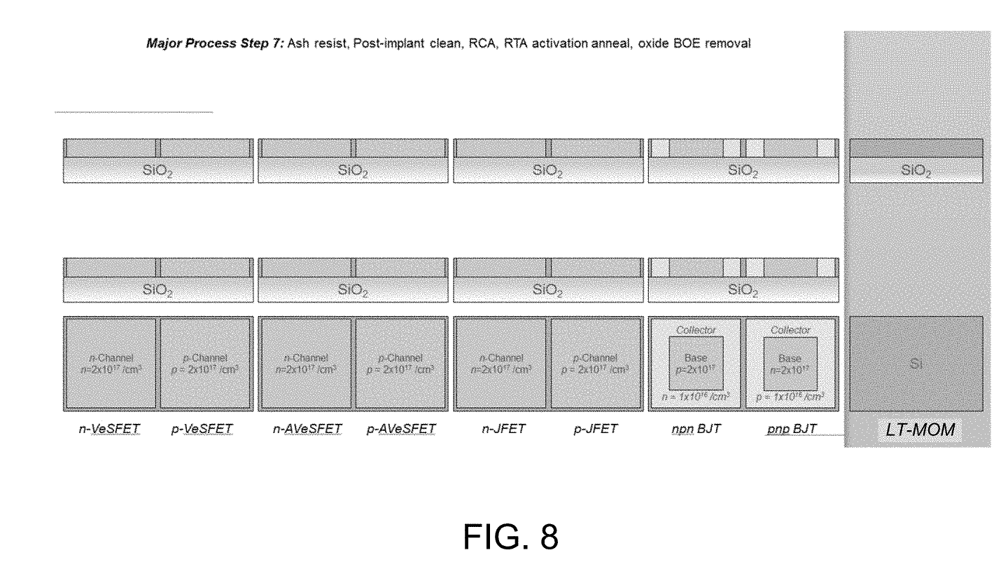

FIG. 8 shows the result of post-implant cleaning and rapid thermal annealing (RTA) activation anneal of all four dopant layers in one step and removal of the screen oxide. Following these procedures, the active areas of all devices have been properly doped. It can be appreciated that the RTA parameters are carefully controlled, as they are critical to doping the slit areas in a uniform manner in x, y, and z dimensions.

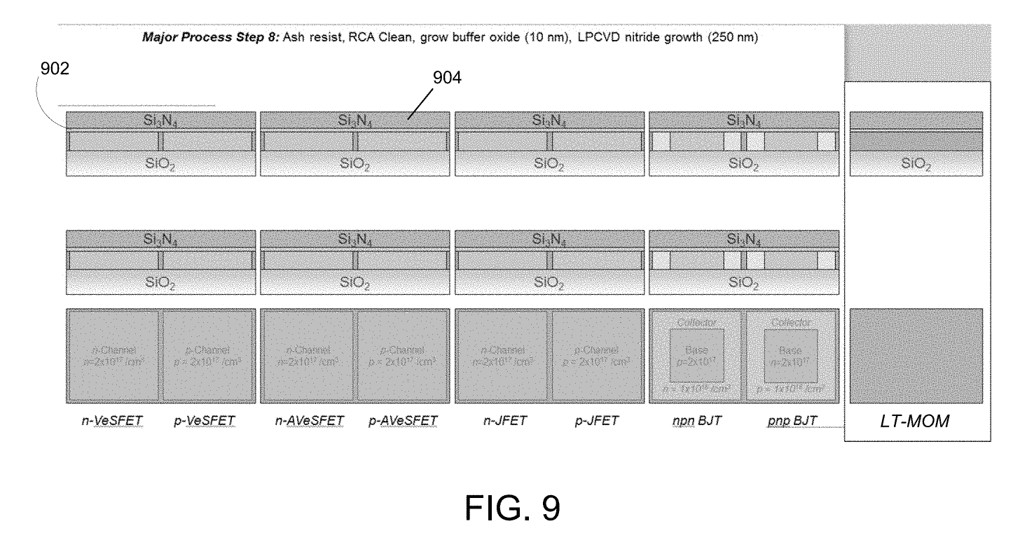

FIGS. 9, 10 and 11 depict the growth of a SiO₂ buffer layer 902, 5 nm to 15 nm thick, followed by a 150 nm to 300 nm thick chemical vapor deposition (CVD) of a Si₃N₄ layer 904, followed by lithography to define the slits of the VeSFET, AVeSFET, JFET, the BJT collectors and LT-MOM capacitor, reactive-ion etching (ME) of Si₃N₄, SiO₂ and the silicon layer.

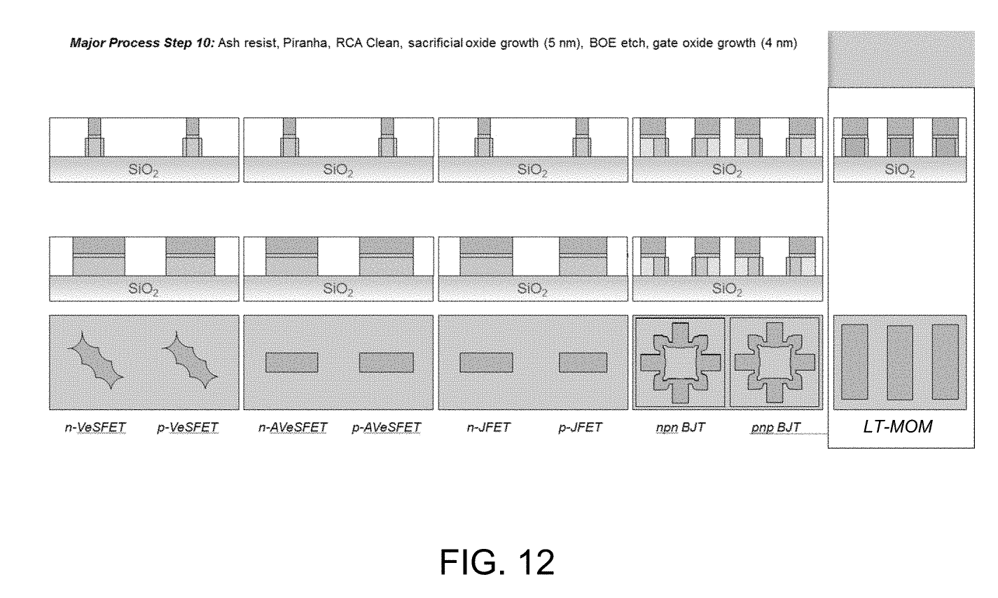

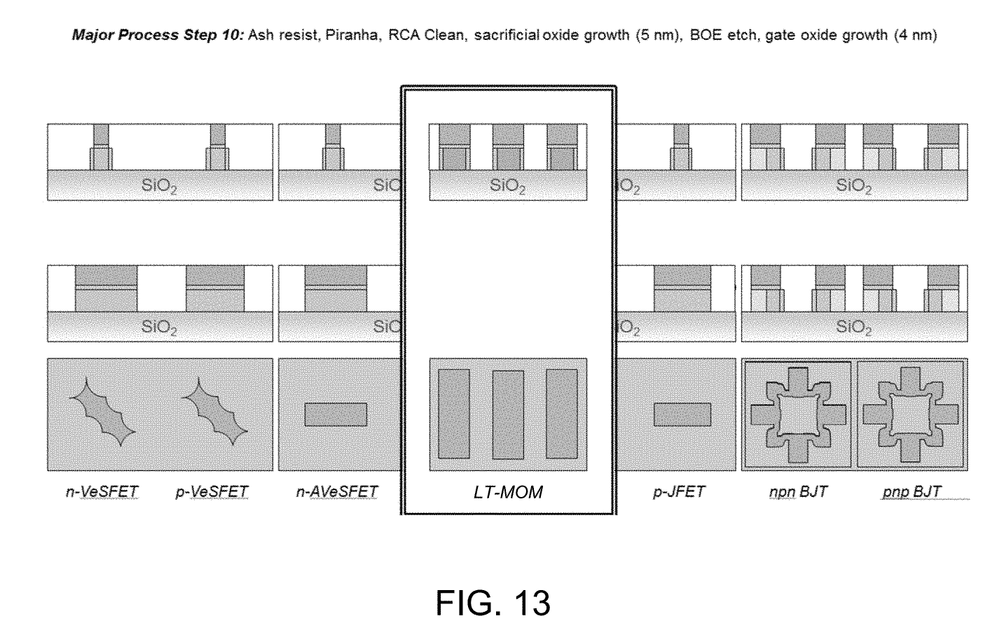

FIGS. 12 and 13 show the results of a post-etch cleaning, followed by a sacrificial SiO₂ growth, the thickness of which may be determined by the final slit width dimension, calculated after the Si RIE etch. A side benefit of the described process embodiment is that the SiO₂ growth mitigates RIE damage on the sidewall. The sacrificial SiO₂ is then stripped via a wet etch and the gate oxide is grown. The thickness of the gate oxide may be determined based on the threshold voltage required by the target circuit to perform as required. It can be appreciated that the crystal planes affect the SiO₂ growth, so care must be taken to match the thickness to the desired threshold voltage. In an example embodiment, the gate oxide thickness may be in the range of 4-8 nm.

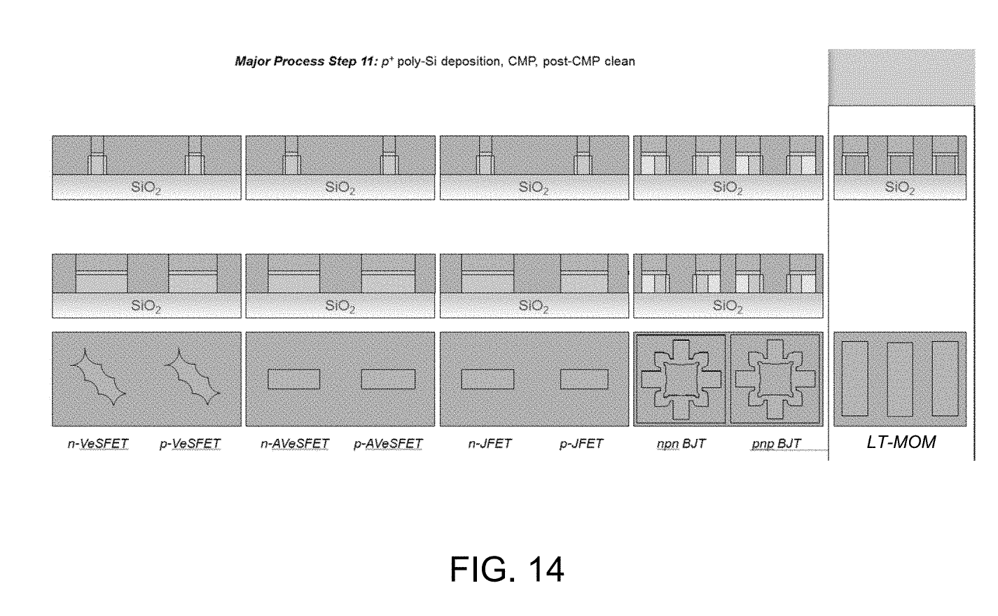

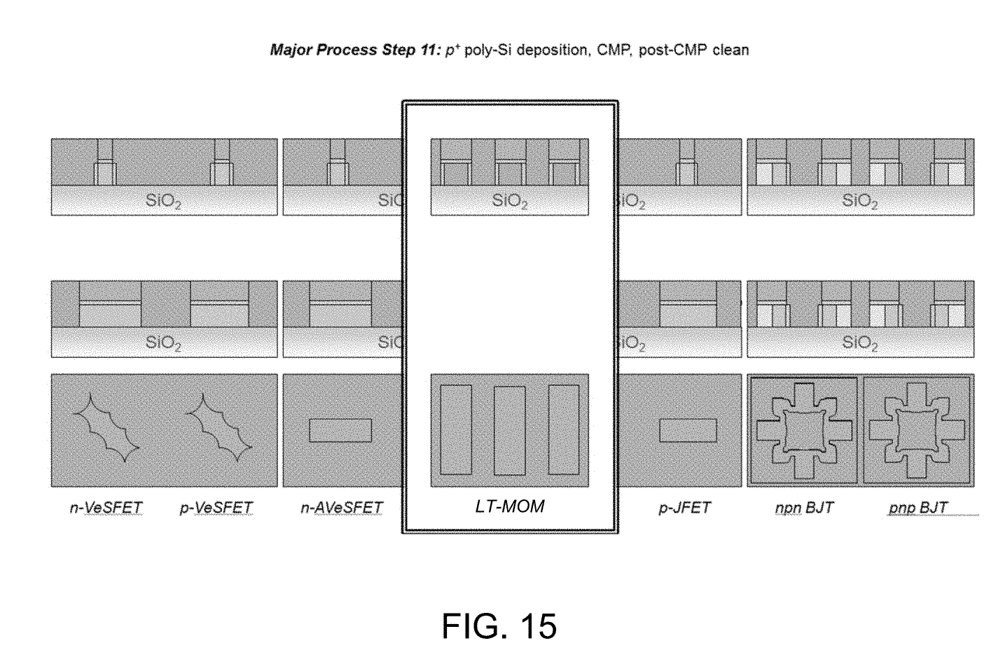

FIGS. 14 and 15 depict the CVD deposition of a p+ doped polysilicon, using boron as a dopant at a concentration greater than 1×10¹⁹, followed by chemical-mechanical planarization (CMP) to planarize the surface.

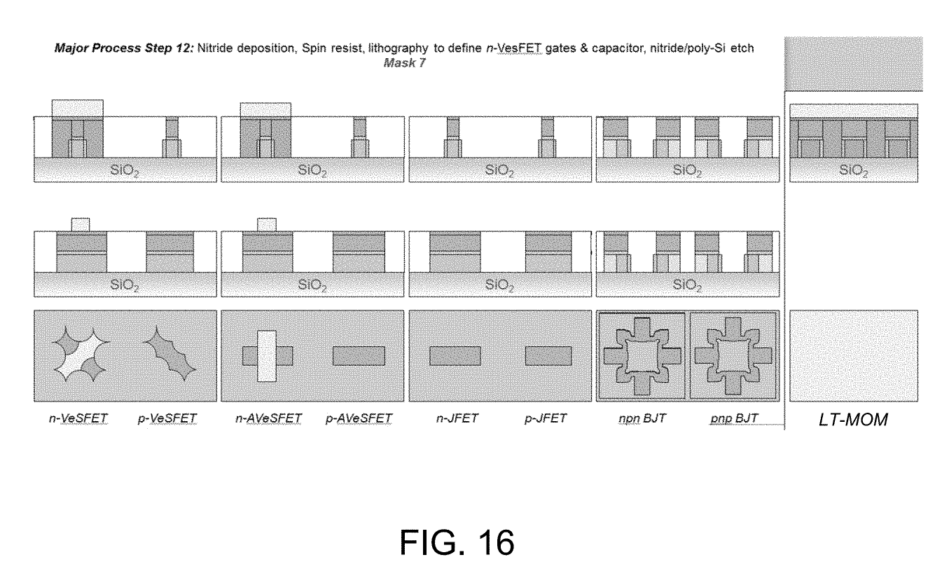

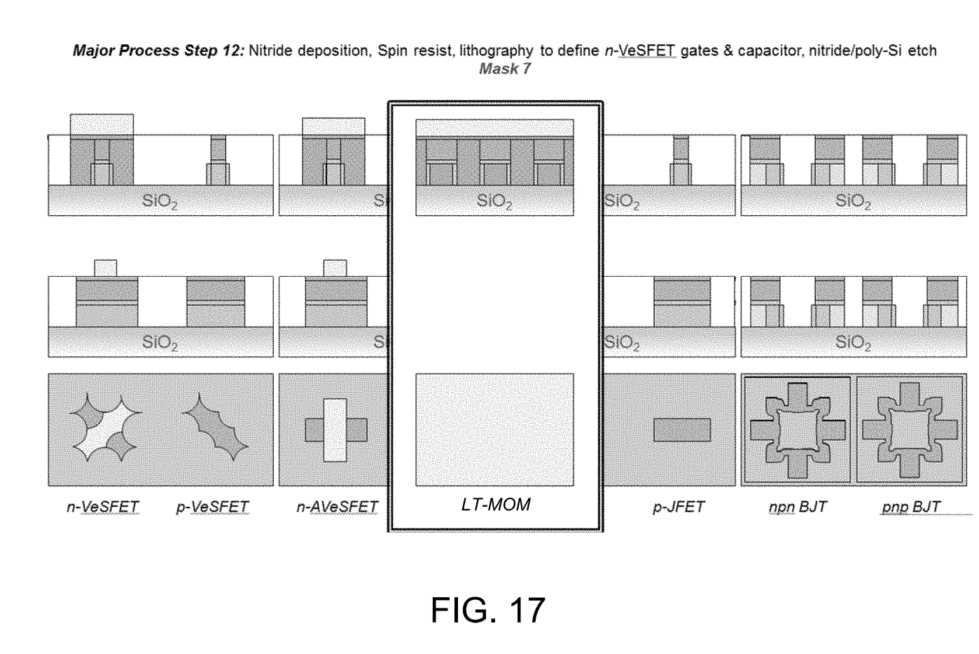

FIGS. 16 and 17 depict the CVD deposition of Si₃N₄, approximately 100 nm thick in an example embodiment. The process further implements lithography to define the gate or filler regions of the n-VeSFET, n-AVeSFET and the LT-MOM capacitor, then etch the Si₃N₄ and SiO₂ followed by polysilicon etch.

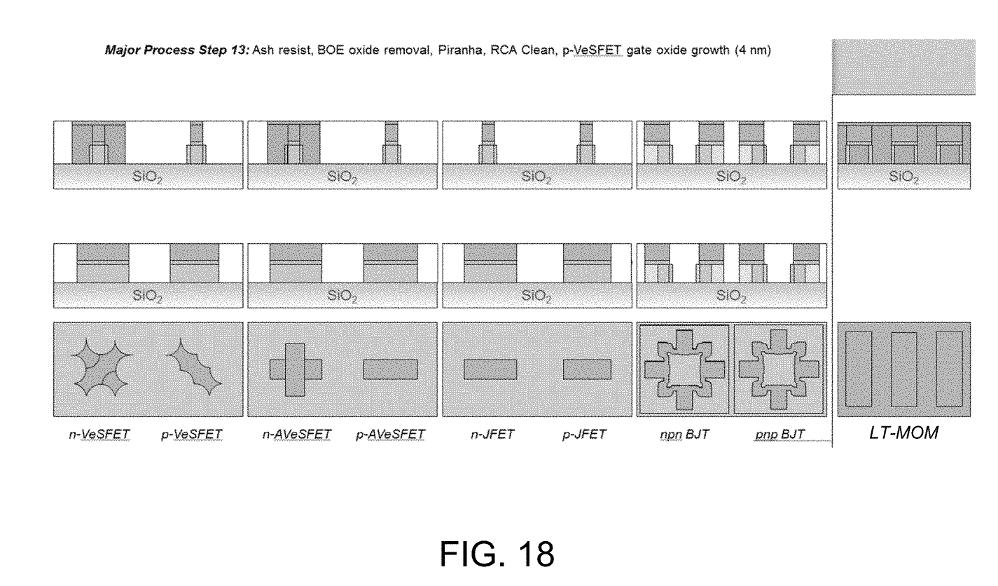

FIG. 18 depicts the etching of the previous gate oxide from the p-VeSFET, p-AVeSFET, JFET and emitter regions of the BJT, then regrowth of a gate SiO₂. The thickness of the gate SiO₂ is determined by the threshold voltage required by the target circuit to perform as required. It can be appreciated that the crystal planes affect the SiO₂ growth so care must be taken to match the thickness to the desired threshold voltage.

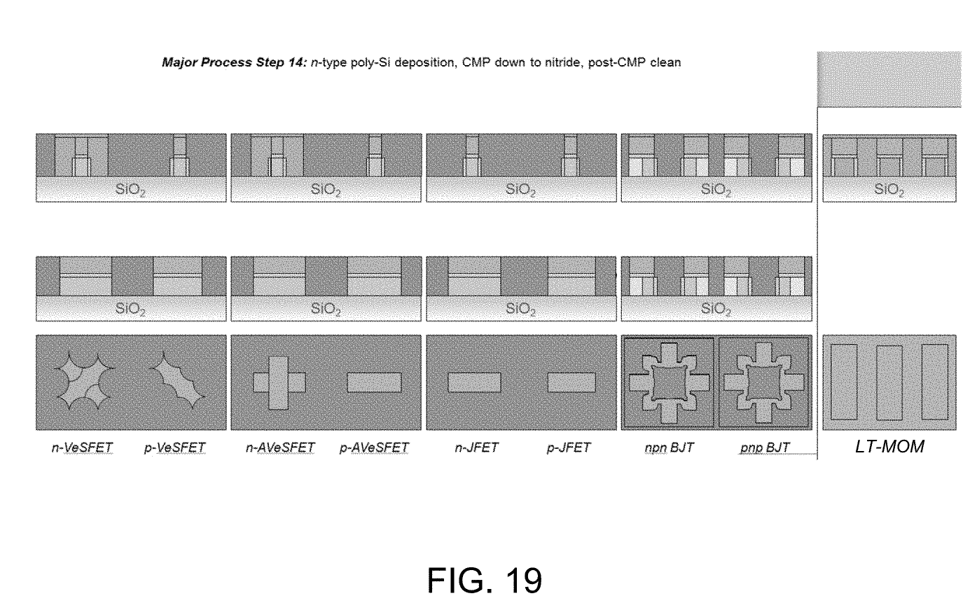

FIG. 19 depicts the CVD deposition of n+ doped polysilicon, using phosphorous or arsenic as a dopant at a concentration greater than 1×10¹⁹, followed by a CMP to planarize the surface.

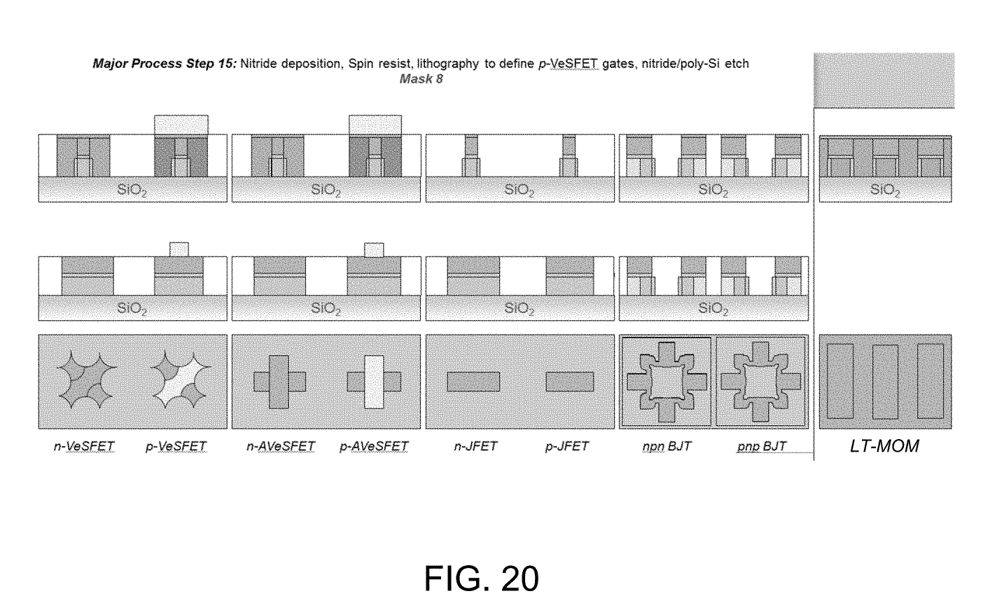

FIG. 20 depicts the CVD deposition of Si₃N₄, approximately 100 nm thick in an example embodiment. The process further implements lithography to define the gate regions of the p-VeSFET, p-AVeSFET. The polysilicon is then etched, removing the polysilicon from the JFET and BJT emitter regions. Upon completion of the processing steps as depicted through FIG. 20, the VeSFET and AVeSFET are physically defined.

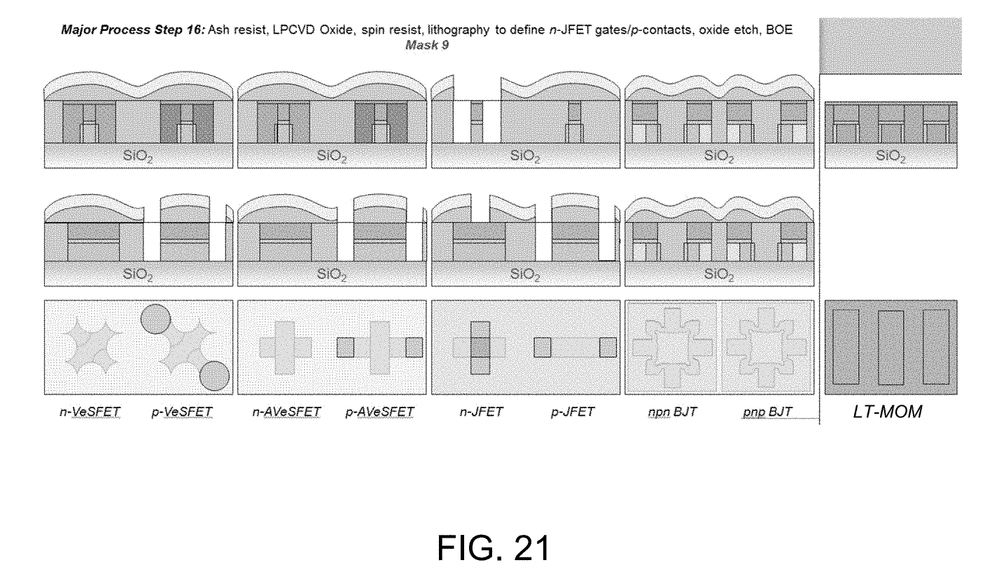

FIG. 21 depicts the CVD growth of a field oxide, SiO₂ at a thickness of 250-450 nm in this example embodiment. The process further implements lithography to define the gate pillar of the n-VeSFET, the slit channel of p-AVeSFET, gate n-JFET and p-JFET source and drain (S/D) channel contact. This process step creates an area suitable for adding an epitaxial layer in a later step, to grade the doping of the contact region of the transistor.

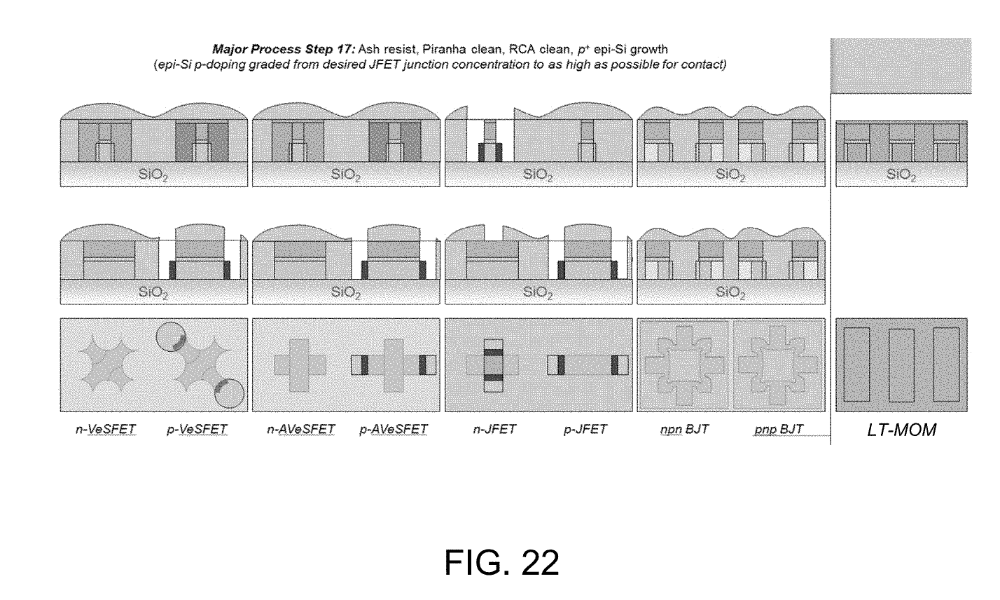

FIG. 22 depicts a clean followed by epitaxial growth of a thin layer of p+ silicon with a concentration of greater than 1×10²⁰, to create a graded contact to the S/D of the p-JFET, the pn junction of the n-JFET, the S/D contacts of p-AVeSFET and the gate contact to the pillar of the n-VeSFET.

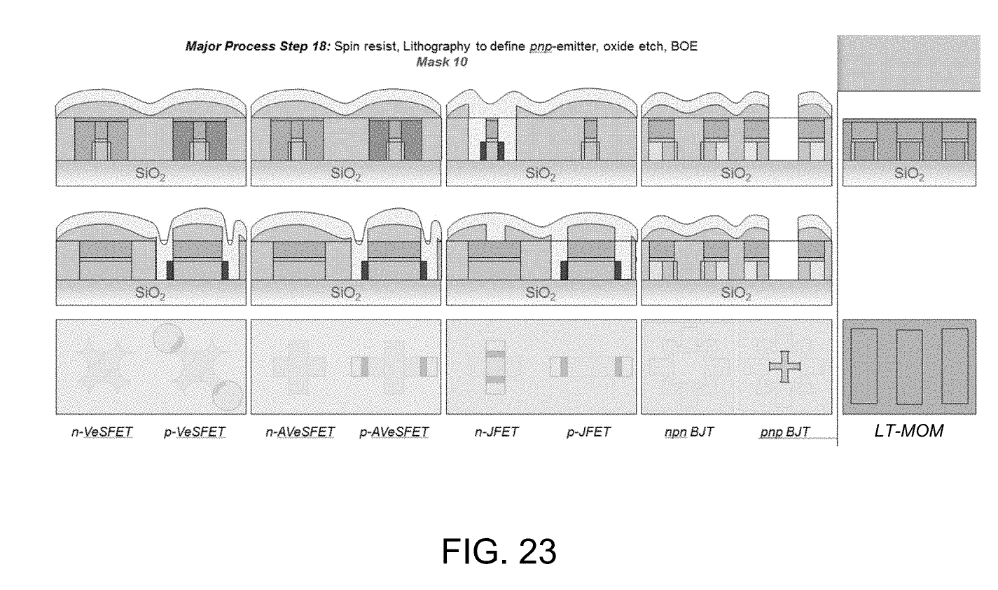

FIG. 23 depicts an implementation of lithography to define the emitter region of the pnp BJT, and to etch Si₃N₄ and SiO₂.

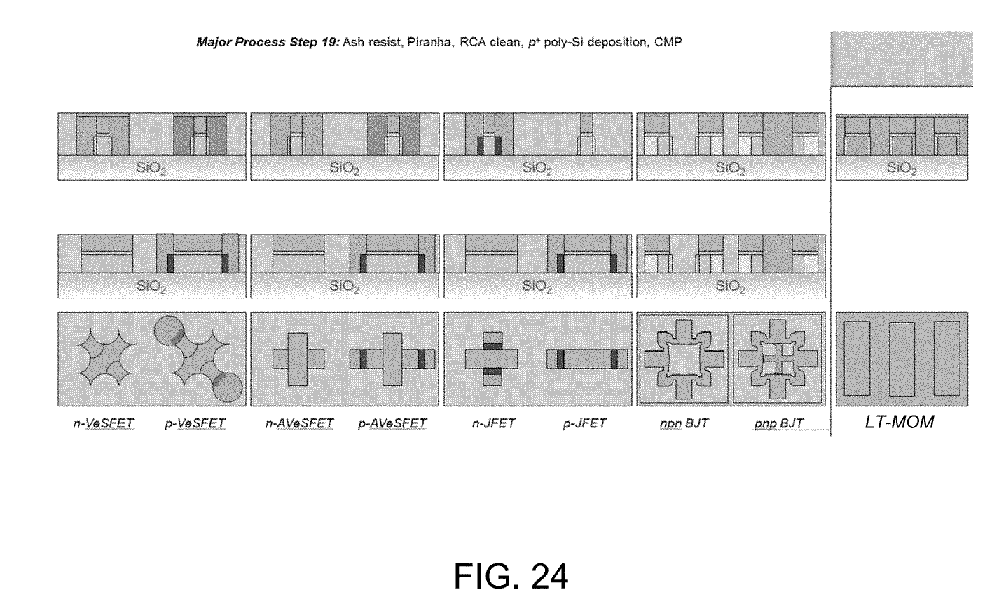

FIG. 24 depicts a CVD deposition of p+ doped polysilicon, using boron as a dopant at a concentration greater than 1×10²⁰, followed by chemical-mechanical planarization (CMP) to planarize the surface. This process step creates the emitter of the pnp BJT, S/D contacts to the p-VeSFET, p-AVeSFET and p-JFET and the gate contact to the n-JFET.

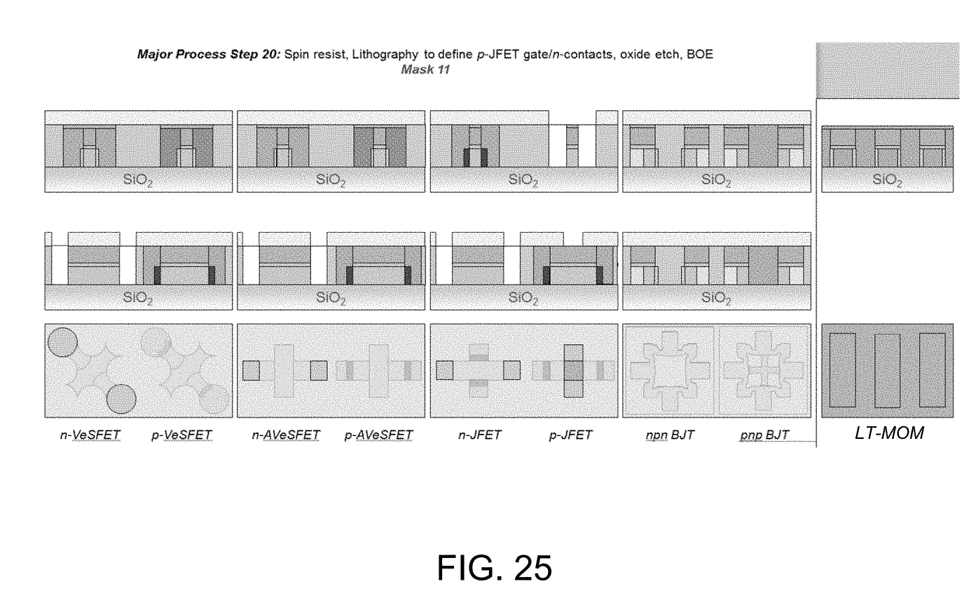

FIG. 25 depicts an implementation of lithography that defines the pn junction of the p-JFET, the S/D contact of the n-JFET, the S/D contacts of the n-AVeSFET, and the gate pillars of p-VeSFET. This process step creates an area suitable for adding an epitaxial layer in a later step, to grade the contact region of the transistor.

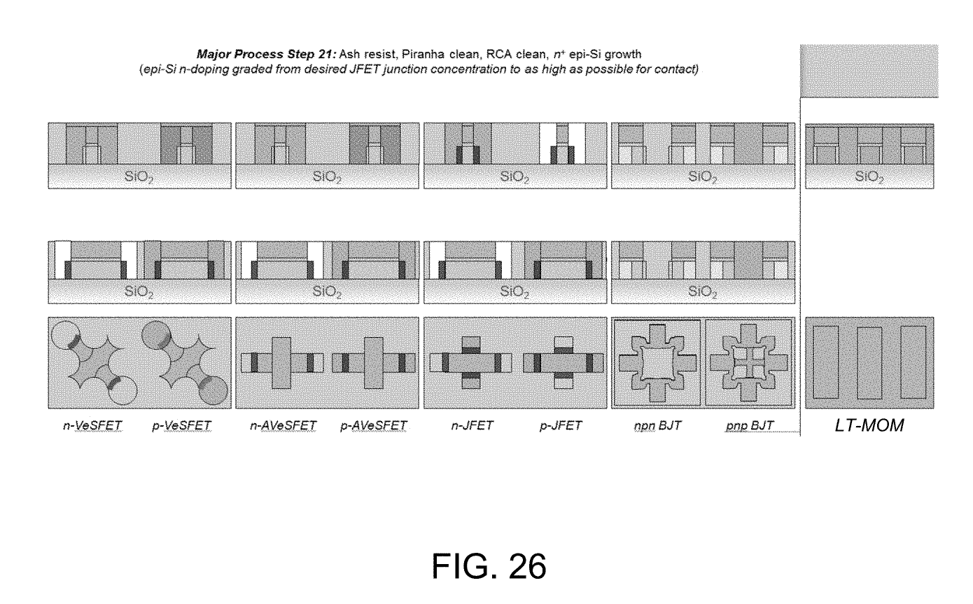

FIG. 26 depicts a clean followed by epitaxial growth of a thin layer of n+ silicon with a concentration greater than 1×10²⁰, to create a graded contact to the S/D of the p-JFET, the pn junction of the p-JFET and fills up the S/D contacts of n-AVeSFET and the gate contact to the pillar of the n-VeSFET.

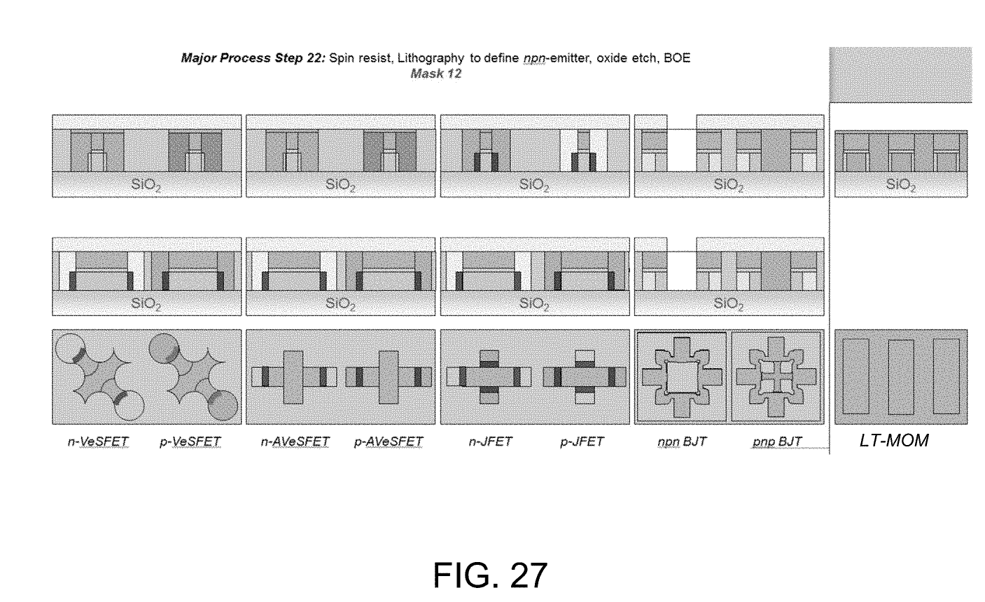

FIG. 27 depicts an implementation of lithography that defines the emitter of the npn BJT and etches the Si₃N₄ and SiO₂

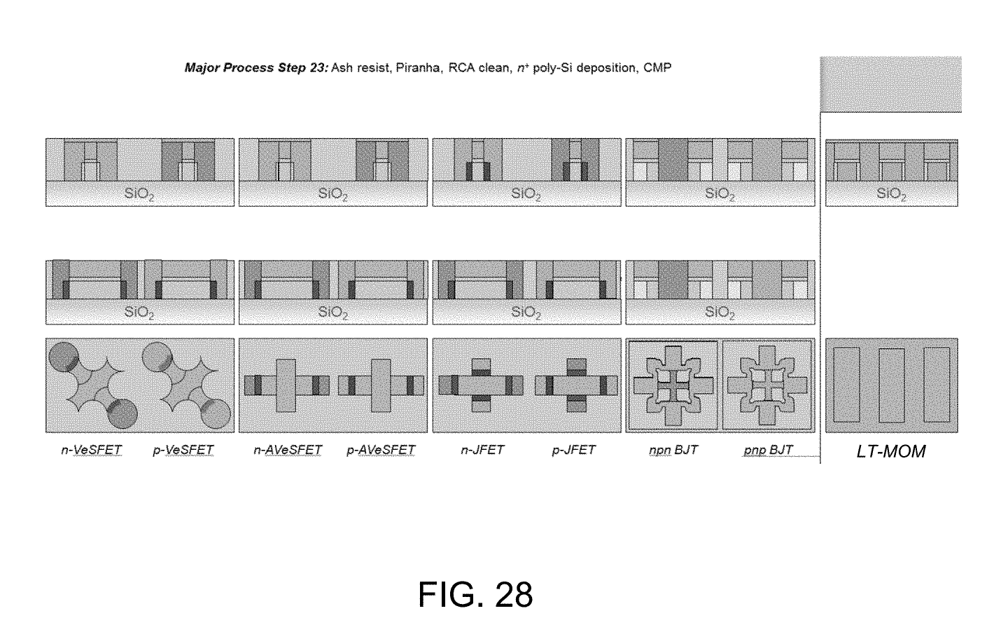

FIG. 28 depicts an CVD deposition of n+ doped polysilicon, using phosphorous or arsenic as a dopant at a concentration greater than 1×10²⁰, followed by chemical-mechanical planarization (CMP) to planarize the surface. This process step creates the emitter of the npn BJT and fills up the S/D contacts for the n-VeSFET, n-AVeSFET and n-JFET and gate contact to the p-JFET.

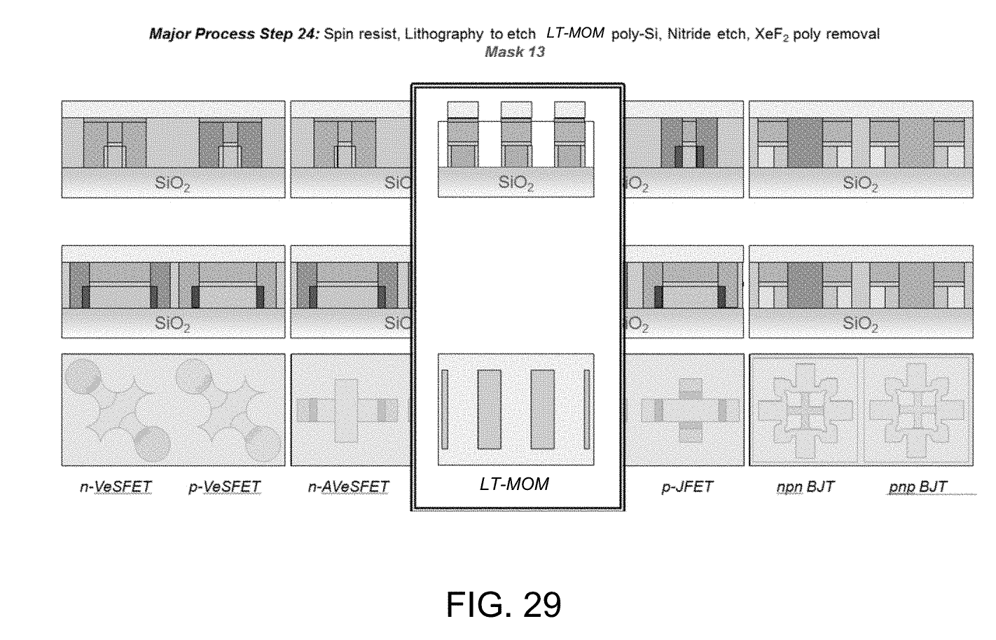

FIG. 29 depicts an implementation of lithography that defines the LT-MOM area to etch the p+ poly from the capacitor fingers. A wet or dry etch process may be used. This process step creates one plate of the LT-MOM capacitor.

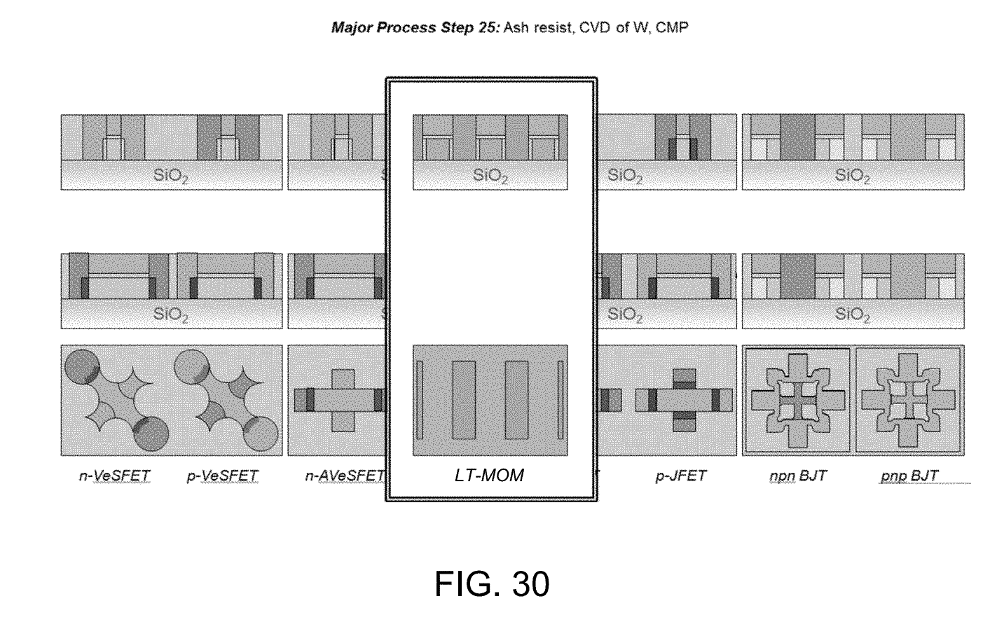

FIG. 30 depicts a CVD deposition of tungsten to fill the trench of the LT-MOM capacitor, followed by CMP. This process step creates the first metal contact of the LT-MOM capacitor.

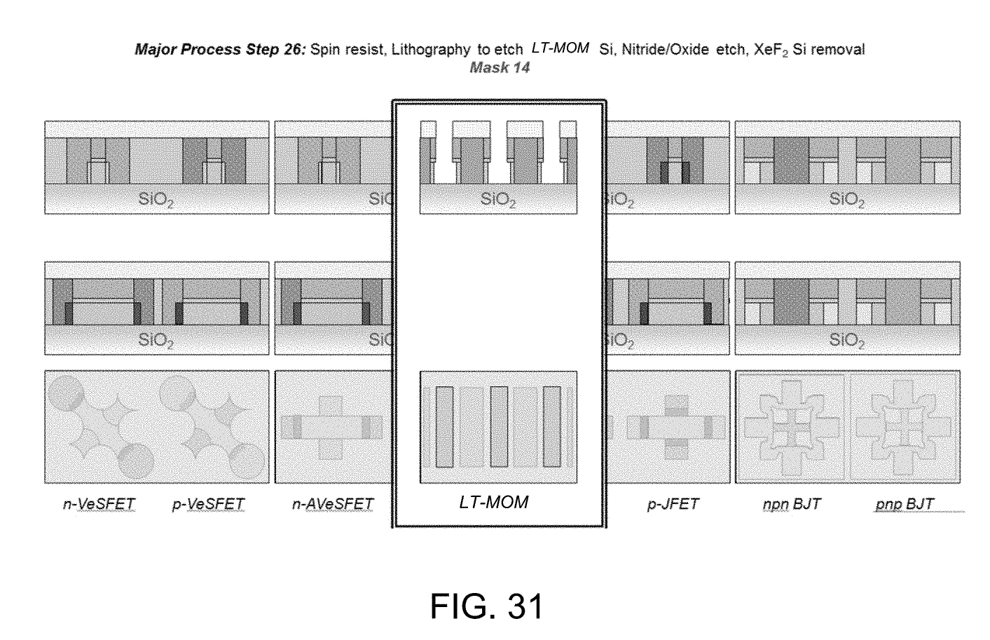

FIG. 31 depicts an implementation of lithography that defines a backfill finger of the LT-MOM capacitor and etches the Si₃N₄/SiO₂ layer, followed by silicon etch, which can be either wet, for example TMAH, or dry, for example XeF₂. This creates a backfill area to create the second plate of the LT-MOM capacitor.

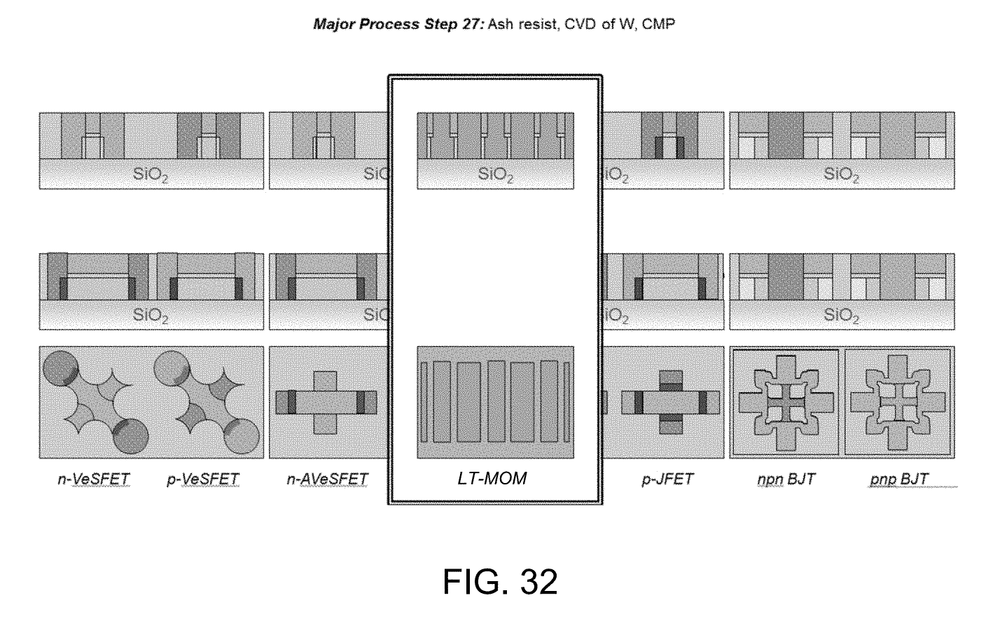

FIG. 32 depicts a CVD deposition of tungsten to fill the trench of the LT-MOM capacitor, followed by CMP. This process step creates the 2nd metal contact of the LT-MOM capacitor.

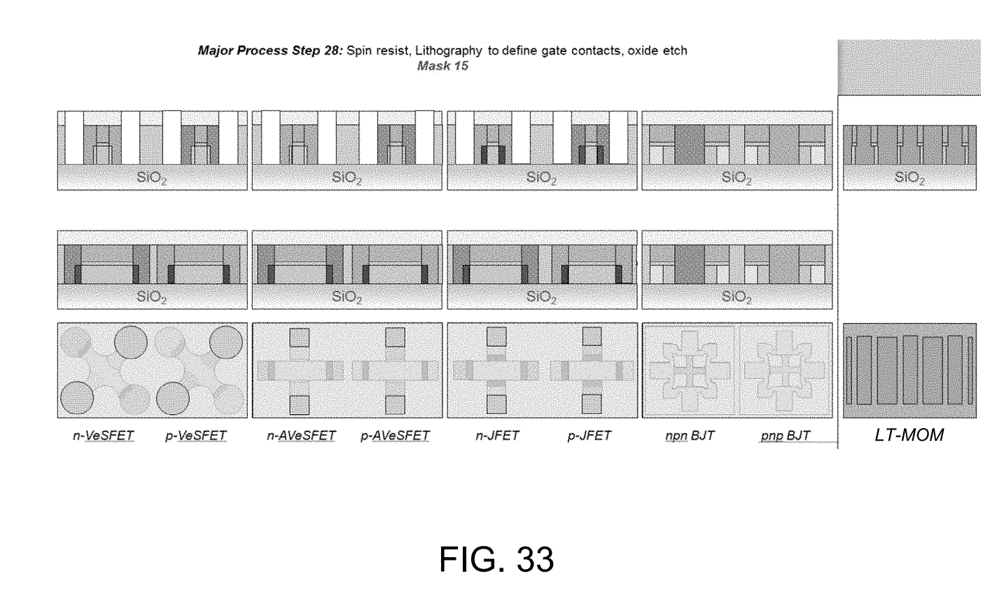

FIG. 33 depicts an implementation of lithography that defines gate contacts to the n-VeSFETs, p-VeSFETs, n-AVeSFETs, p-AVeSFETs, n-JFETs and p-JFETs, and the etching of Si₃N₄ and SiO₂

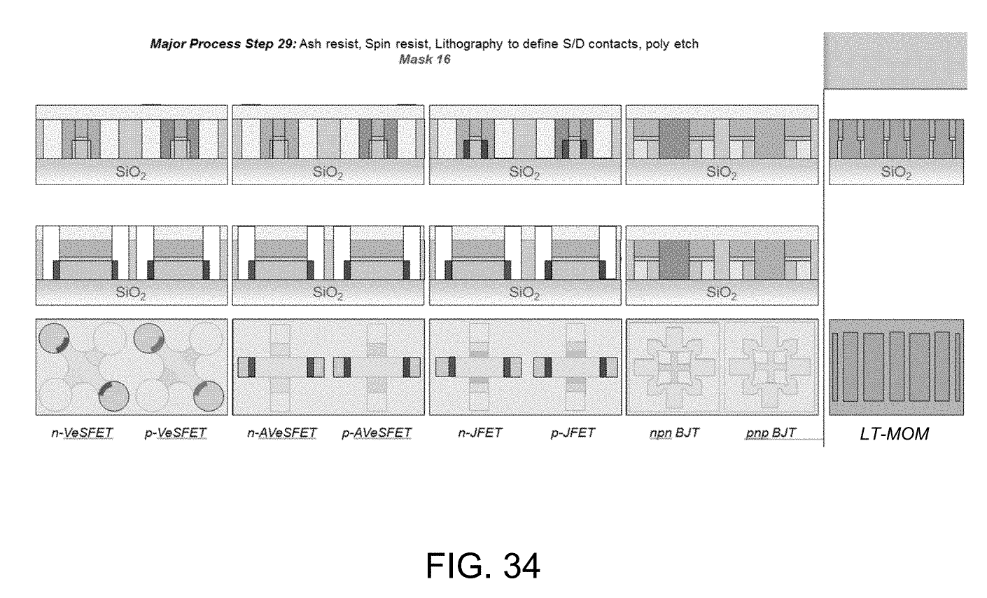

FIG. 34 depicts an implementation of lithography that defines S/D contacts of the n-VeSFETs, p-VeSFETs, n-AVeSFETs, p-AVeSFETs, n-JFETs and p-JFETs, by etching out the polysilicon fill.

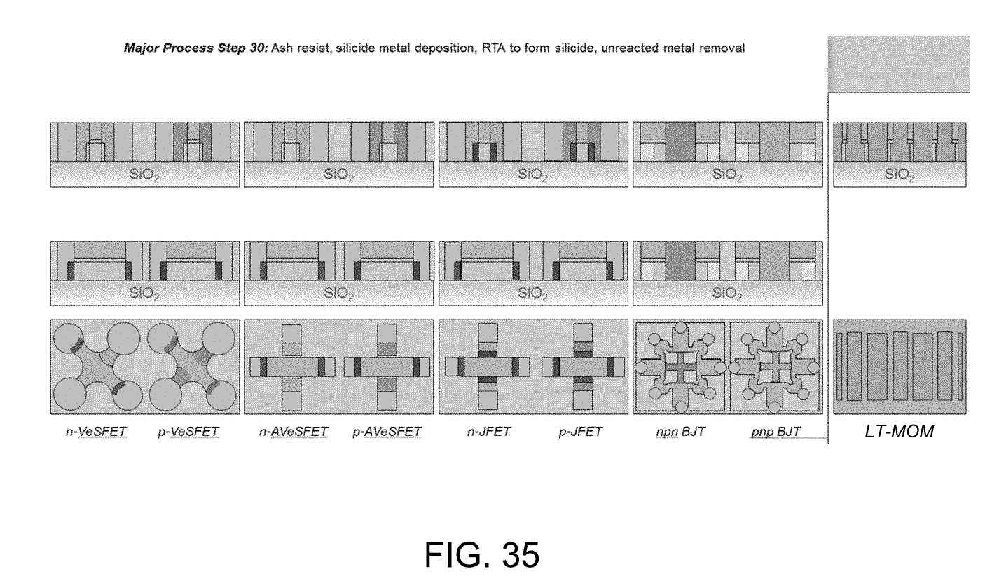

FIG. 35 depicts physical vapor deposition (PVD) of a Nickel layer (approximately 10 nm thick in the described embodiment, although other thicknesses may be used), and RTA to form nickel silicide. This process step creates a layer of NiSi on the gate, S/D and Collector/Base/Emitter contacts of the VeSFET, AVeSFET, JFET, BJT and LT-MOM capacitor devices.

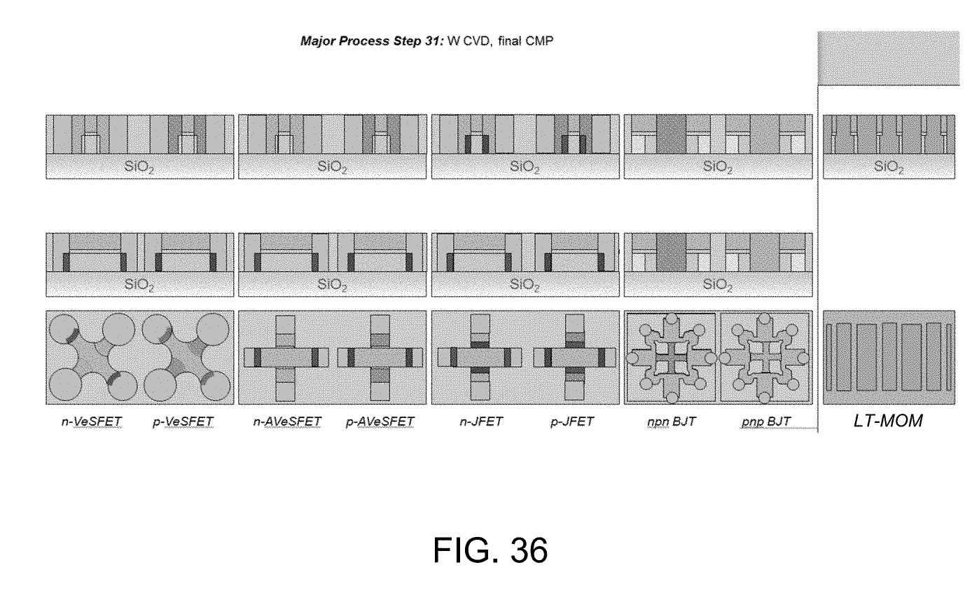

FIG. 36 depicts a CVD deposition of tungsten, and a final CMP to contact all device terminals.

The Tungsten pillars allow these wafers to go into standard back end of line (BEOL) processing. It is also noted that the wafer is built on SOI so that wafer scale technology may be used to stack the wafers up and take advantage of three-dimensional (3D) circuit architecture.

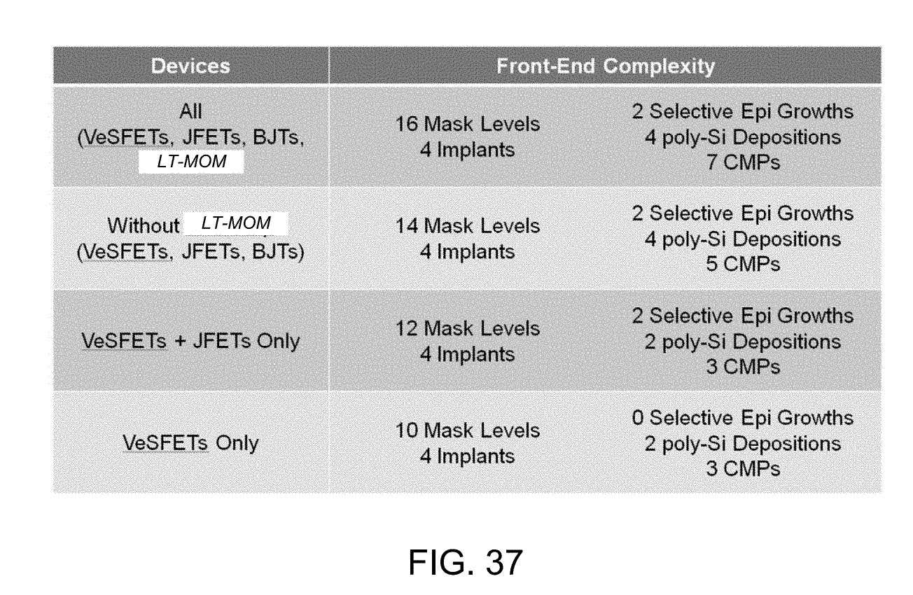

FIG. 37 shows a table that describes process flow complexity for integrations several combinations of device types.

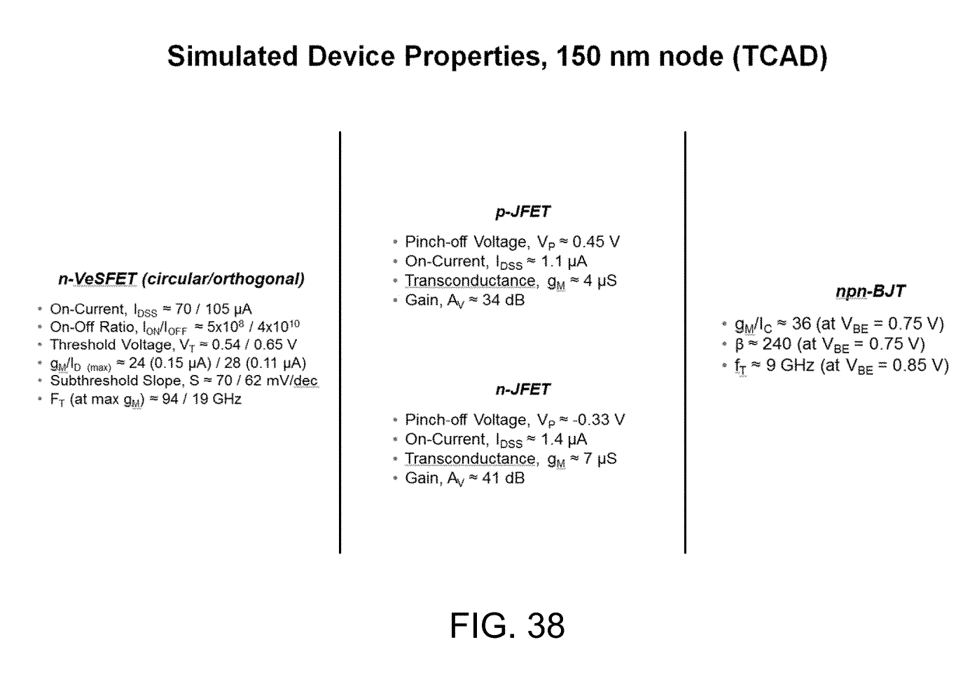

FIG. 38 shows technology computer aided design (TCAD) modeled properties of the various devices.

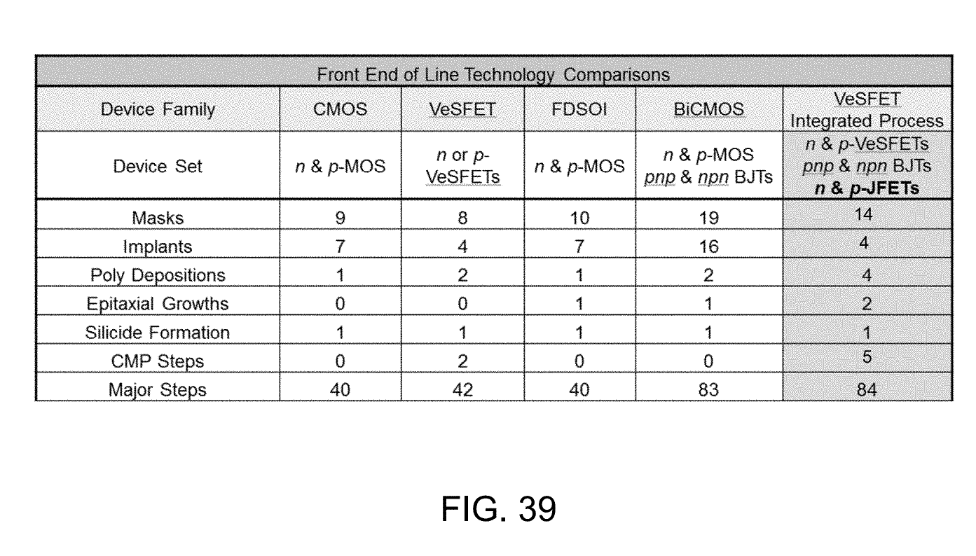

FIG. 39 shows a comparison of the process flow of the described embodiments to other existing process flow technologies. The process flow of the example embodiments described herein is shown in the shaded column to the far right.

### Constituent Device Descriptions

Analog VeSFETs (Complementary n-Channel and p-Channel)

The VeSFET in general has some basic advantages as compared to the State-of-the-Art MOS (Metal-Oxide-Semiconductor) transistors. The device is a majority carrier device with a conducting channel based on depletion widths for turn-on and turn-off characteristics as opposed to a surface inversion layer. This is similar to a JFET in operation and has unique advantages over standard MOSFETs. The channel is formed in the bulk of the silicon, away from the oxide interfaces, which improves carrier mobility, and 1/F (flicker) noise. The gate oxide is comparably thicker than a standard MOSFET, which reduces gate leakage (tunneling current). The gate oxide can be made out of thermally-grown SiO₂, leveraging decades of process experience and low cost processing. The ratio of the “ON” current to the “OFF” current (I_{ON}/I_{OFF}) has been measured to be at least eight orders of magnitude better than the best-in-class FinFET devices.

The VeSFET has dual, symmetric gates. This allows many unique digital and analog capabilities. For example, adjustment of the threshold voltage, V_{T}, may be made with the second gate. Higher order Boolean digital processing is possible with fewer transistors as compared to standard devices (one transistor can be an “AND” Boolean function as opposed to two MOSFETs). It is possible to build high input impedance, unity gain, inverting amplifiers. As conceived this would be the first of its kind.

The VeSFET is built on a Silicon-On-Insulator (SOI) substrate, and is trench isolated in 360 degrees, so it effectively is oxide isolated everywhere as opposed to junction isolated, which has problems with leakage currents. The VeSFET has lower leakage currents as a result, and shows much higher levels of overall electrical isolation.

The geometry of the layout allows a compact design, which inherently has low parasitic resistance and capacitance. This geometry allows for a highly efficient design yielding high speed per unit of power consumption. The geometry also allows for a highly dense digital layout in equivalent digital Gates/Area metric. This adds digital capability (more transistors), and saves money (wafer cost is constant, but VeSFETs achieve more transistor/chip and/or more chips/wafer).

The VeSFET has regularly arrayed metal pillars that run the entire vertical dimension of the transistors. This creates a naturally low resistance path for current to get in and out of the transistor. These pillars act as a natural heat sink in a dense digital, microprocessor-like, layout. This would allow higher digital operations without fear of thermal issues.

The standard high speed/bandwidth VeSFET is an all circle, unit-size cell layout to achieve the advantages attributed to geometry, as described above. This restricts both the slit width and length to be the process minimum size. The analog performance is far superior to the FinFET and planar MOSFETs of similar process capability, but it is not adjustable. The “Analog” VeSFET described herein addresses this limitation.

All devices can be arrayed in parallel to effectively adjust the W (width), but the “Analog” VeSFET's L (length) is now designer adjustable, similar to that of a standard transistor. The output impedance can be increased with increasing L at the expense of speed (lower F_{T}). Current sources are excellent examples where this device would be preferred over the standard circular VeSFET. The gate area can now be increased to improve, the already superior to a standard transistor 1/F noise. For a given current, the operating point can now be adjusted to achieve a desired g_{M} (transconductance).

JFETs (Complementary n-channel and p-channel)

JFETs exhibit a low 1/F noise, due to their lack of an oxide layer. JFETs are natural depletion mode devices, which exhibit majority carrier current flow.

The integrated process JFET has some unique novel advantages over a standard J-FET. The effective threshold voltage, thus IDSS (V_{GS}=0V) on current, is adjustable by the designer by 2D layout adjustment. Existing process technologies have this fixed. Ultra-deep sub-micron process technologies do not offer the JFET as a device due to its' added complexity and cost. The integrated flow building the JFET orthogonal to standard practices can offer this component at much lower complexity and cost than what exists today. The JFET in the integrated process flow as designed has two symmetrical gates, which allows for another level of effective threshold voltage control.

Bipolar Transistors (Complementary npn and pnp)

Bipolar junction transistors (BJTs) have historically provided numerous benefits over the standard MOSFET for certain applications. These include, but are not limited to, (i) superior transconductance-to-current ratio, g_{M}/I_{C} of almost 38, which is typically at least twice, and usually more than twice, as high as a MOSFET, (ii) higher self gain, g_{M}/g_{OUT}, than the MOSFET −60 dB (npn) vs. 35 dB (NMOS), degrading to less than 15 dB for deep sub-micron NMOS, and (iii) higher speed, F_{T}, vs. operational voltage than the MOSFET.

The npn and pnp BJT fabricated using the described embodiments, which also is oriented laterally, as opposed to the typical vertical orientation of a conventional bipolar transistor, has all the typical advantages plus some unique additional ones.

The lateral structure is consistent with this new standard integrated process flow, and along with the lack of a critical vertical depth for the base, is much easier to fabricate. Higher quality and lower cost will be a result while maintaining the typical bipolar advantages.

The lateral structure improves the collector resistance given the vertical metal pillars are uniform through the Z-direction. Typical bipolar transistors have a deep buried layer, which is high resistance naturally plus the current travels a long path through the silicon to get back up to the surface where the common metallization resides. Both these add significantly to the collector resistance of the common transistor.

The base width is the most critical geometry on the bipolar transistor—the common process and design accomplishes this thin layer through doping and temperature diffusion alone, which is very challenging to control accurately. This new lateral bipolar transistor the base region is defined by very accurate mask and mask alignment tolerances of the deep sub-micron process equipment, and not so much on less controlled process steps.

Due to process challenges and costs it is very unusual, if not impossible, to find an existing alternative process that can integrate ultra-deep sub-micron MOSFETs with analog bipolar transistors. The process of the described embodiments allows this integration with reasonable complexity and cost due to the lateral nature of the structures on SOI.

The designer can now adjust many of the performance characteristics and trade-offs, which in the past was not an option for them. This is a major advantage. For example: (i) speed, F_{T}, vs. breakdown voltage, BV_{CEO} (extending the collector region in two dimensions), (ii) Current gain, β, vs. breakdown voltage, BV_{CEO} (extending the base region in two dimensions); (iii) current gain, β, vs. base resistance, r_{B} (position of the base contact regions in two dimensions).

### Lateral Thermal Metal-Oxide-Metal Capacitor (LT-MOM)

The capacitor is a critical analog “bread-n-butter” component that is required for analog and mixed-signal design, and it should have certain performance characteristics. In the advantages listed below of the LT-MOM as compared to existing available technologies, dielectric permittivity is assumed the same. The LT-MOM initially will use SiO₂ with a relative permittivity of 3.9, but can in the future use high-K dielectrics such as Hafnium dioxide (HfO₂).

Advantages include (i) high density—Farads per unit area (F/μm²), (ii) linearity, voltage coefficient (i.e., capacitance variation with respect to signal voltage), (iii) temperature coefficient (i.e., capacitance variation with respect to temperature), (iv) capacitive density per breakdown voltage (F/μm²/BV), (v) natural matching to at least 10 bits of resolution (˜0.1%), (vi) high ratio of desired capacitance, C_{MAIN}, to unwanted stray capacitance, C_{PARASITIC} (C_{MAIN}/C_{PAR}), and high resonance frequency, (F_{RES}).

The conventional process technologies of today offer numerous flavors of capacitor for different purposes. Cost and complexity are a common issue amongst all options. The process technologies used for linear signal process analog and mixed-signal applications are as follows.

(I) Polysilicon-Polysilicon—this process adds another polysilicon conducting layer and deposited oxide and/or nitride as the dielectric. This type of capacitor is common in analog process technologies.

| | |
|---|---|
| Good density (<1.5 fF/μm²) | GOOD |
| Reasonable linearity (polysilicon has silicide and is | OK |
| highly doped to be more conductive) | |
| Temperature coefficient (polysilicon has silicide). | OK |
| Capacitive density per breakdown (deposited oxide) | OK |
| Natural matching | OK |
| C_{MAIN}/C_{PAR} (about 10X) | OK |
| F_{RES} (polysilicon is too resistive) | POOR |

(II) MIM (Metal-Insulator-Metal)—the capacitor is built up in the metal stack to reduce the parasitic capacitance, and the insulator/dielectric is deposited rather than grown. [65 nm Process used as comparison]

| | |
|---|---|
| Good density (<1.9 fF/μm²) | GOOD |
| Good linearity (deposited oxide) | OK |
| Temperature coefficient (deposited oxide) | OK |
| Capacitive density per breakdown (deposited oxide) | OK |
| Natural matching | OK |
| C_{MAIN}/C_{PAR} (>10X) | GOOD |
| F_{RES} (deposited oxide, less parasitic capacitances) | GOOD |

MOM (Metal-Oxide-Metal)—the capacitor is built from the extensive number of interconnect metal layers. [65 nm Process used as comparison: 5-Layers].

| | |
|---|---|
| Good density (<2.4 fF/μm²) | GOOD |
| Ok linearity (oxide tends to be poor quality) | OK |
| Temperature coefficient (oxide tends to be poor quality) | OK |
| Capacitive density per breakdown (deposited oxide) | OK |
| Natural matching (interconnect not controlled enough) | POOR |
| C_{MAIN}/_{CPAR} (>10X) | GOOD |
| F_{RES} (oxide tends to be poor quality) | OK |

LT-MOM fabricated using the described embodiments—lateral thick metal terminals with a thermally grown oxide using the gate oxide process. This is considered the highest quality oxide in the semiconductor industry given its critical role in all transistor performance.

| | |
|---|---|
| GREAT density (~10 fF/μm²) - for 3.5 nm gate oxide. | GREAT |

Factor of 5X improvement in an older, less expensive process node

| | |
|---|---|
| GREAT linearity (metals with the best quality oxide). | GREAT |
| Temperature coefficient (metals w/best quality oxide). | GREAT |
| Capacitive density per breakdown (best quality oxide) | GREAT |
| Natural matching (most controlled process step) | GREAT |
| C_{MAIN}/C_{PAR} (>40X, trench isolated SOI) | GREAT |
| F_{RES} (metals with the best quality oxide) | GREAT |

The LT-MOM capacitor fabricated using the described embodiments can be implemented on the back-end of the integrated process flow without undue complication. When fabricated according to the described embodiments, the LT-MOM may be the most ideal capacitor ever built to date in the semiconductor industry.

FIGS. 40A, 40B, 40C, and 40D illustrate example methods of semiconductor fabrication according to the embodiments. FIG. 40A shows an example embodiment of a method of fabricating a semiconductor device, comprising forming 4002, on a silicon on insulator (SOI) wafer, at least one of an n channel, digital VeSFET, a p channel, digital VeSFET, an n channel, analog VeSFET, and a p channel, analog VeSFET, and forming 4004, on the SOI wafer and within the same process flow, at least one of a JFET, a BJT and a LT-MOM capacitor.

FIG. 40B shows an example embodiment of a method of fabricating a semiconductor device, comprising forming 4006, on a silicon on insulator (SOI) wafer, at least one of an n channel, digital VeSFET, a p channel, digital VeSFET, an n channel, analog VeSFET, and a p channel, analog VeSFET, and forming 4008, on the SOI wafer and within a single process flow, at least one of a an n channel JFET, a p channel JFET, an npn BJT, a pnp BJT, and a LT-MOM capacitor.

FIG. 40C shows an example embodiment of a method of enhancing performance of a semiconductor node, comprising modifying 4010 a design of the semiconductor node, according to a three-dimensional architecture, to form a modified semiconductor node, and fabricating 4012 the modified semiconductor node on substrate, along with at least one other node of a different node type.

FIG. 40D shows an example embodiment of a method of enhancing performance of semiconductor nodes, comprising modifying 4014 a design of a first semiconductor node, according to a first three-dimensional architecture, to form a first modified semiconductor node, modifying 4016 a design of a second semiconductor node, according to a second three-dimensional architecture, to form a second modified semiconductor node, and fabricating 4018 the first modified semiconductor node and the second modified semiconductor node on substrate.

While example embodiments have been particularly shown and described, it will be understood by those skilled in the art that various changes in form and details may be made therein without departing from the scope of the embodiments encompassed by the appended claims.

What is claimed is:

1. A method of fabricating a semiconductor device, comprising:
within a single process flow:
forming, on a silicon on insulator (SOI) wafer, at least one of:
an n channel, digital VeSFET;
a p channel, digital VeSFET;
an n channel, analog VeSFET;
a p channel, analog VeSFET; and
forming, on the SOI wafer, at least one of a JFET, a BJT and a LT-MOM capacitor.

2. The method of claim 1, further comprising forming the at least one of an n channel, digital VeSFET, a p channel, digital VeSFET, an n channel, analog VeSFET, and a p channel, analog VeSFET, according to a periodic design based on a unit circle.

3. The method of claim 1, wherein forming the at least one of an n channel, digital VeSFET, a p channel, digital VeSFET, an n channel, analog VeSFET, and a p channel, analog VeSFET, comprises one or more of:
(i) defining a mesa;
(ii) growing sacrificial oxide and n-VeSFET gate oxide;
(iii) depositing p⁺ poly-Si for n-VeSFET gates;
(iv) performing chemical-mechanical planarization (CMP);
(v) depositing a nitride protective layer;
(vi) defining an n-VeSFET gate;
(vii) growing a p-VeSFET gate oxide;
(viii) depositing n⁺ poly-Si for p-VeSFET gates;
(ix) depositing a nitride protective layer; and
(x) defining an p-VeSFET gate.

4. The method of claim 1, wherein forming the BJT comprises one or more of:
(i) growing screen oxide for at least one implant;
(ii) etching at least one alignment mark;
(iii) doping an npn collector;
(iv) doping a pnp collector;
(v) doping a p-channel and npn base;
(vi) doping an n-channel and pnp base;
(vii) performing an activation anneal and an oxide removal;
(viii) defining an npn emitter;
(ix) depositing an n⁺ poly-Si for npn-emitter and n-contact fill; and
(x) performing chemical-mechanical planarization (CMP).

5. The method of claim 1, wherein forming the JFET comprises one or more of:
(i) performing an oxide fill;
(ii) defining an n-JFET gate and p-contact; and
(iii) defining a p-JFET gate and n-contact.

6. The method of claim 1, wherein forming the LT-MOM capacitor comprises one or more of:
(i) defining an LT-MOM capacitor;
(ii) etching a poly-Si layer with XeF₂;
(iii) performing a chemical vapor deposition (CVD) of tungsten; and
(iv) performing chemical-mechanical planarization (CMP).

7. A method of fabricating a semiconductor device, comprising:
within a single process flow:
forming, on a silicon on insulator (SOI) wafer, at least one of:
an n channel, digital VeSFET;
a p channel, digital VeSFET;
an n channel, analog VeSFET;
a p channel, analog VeSFET; and
forming, on the SOI wafer, at least one of:
an n channel JFET;
a p channel JFET;
an npn BJT;
a pnp BJT; and
a LT-MOM capacitor.

8. The method of claim 7, further comprising forming the at least one of an n channel, digital VeSFET, a p channel, digital VeSFET, an n channel, analog VeSFET, and a p channel, analog VeSFET, according to a periodic design based on a unit circle.

9. The method of claim 7, wherein forming the at least one of an n channel, digital VeSFET, a p channel, digital VeSFET, an n channel, analog VeSFET, and a p channel, analog VeSFET, comprises one or more of:
(i) defining a mesa;
(ii) growing sacrificial oxide and n-VeSFET gate oxide;
(iii) depositing p⁺ poly-Si for n-VeSFET gates;
(iv) performing chemical-mechanical planarization (CMP);
(v) depositing a nitride protective layer;
(vi) defining an n-VeSFET gate;
(vii) growing a p-VeSFET gate oxide
(viii) depositing n⁺ poly-Si for p-VeSFET gates;
(ix) depositing a nitride protective layer; and
(x) defining an p-VeSFET gate.

10. The method of claim 7, wherein forming the BJT comprises one or more of:
(i) growing screen oxide for at least one implant;
(ii) etching at least one alignment mark;
(iii) doping an npn collector;
(iv) doping a pnp collector
(v) doping a p-channel and npn base;
(vi) doping an n-channel and pnp base;
(vii) performing an activation anneal and an oxide removal;
(viii) defining an npn emitter;
(ix) depositing an n⁺ poly-Si for npn-emitter and n-contact fill;
(x) performing chemical-mechanical planarization (CMP).

11. The method of claim 7, wherein forming the JFET comprises one or more of:
(i) performing an oxide fill;
(ii) defining an n-JFET gate and p-contact;
(iii) defining a p-JFET gate and n-contact.

12. The method of claim 7, wherein forming the LT-MOM capacitor comprises one or more of:
(i) defining an LT-MOM capacitor;
(ii) etching a poly-Si layer with XeF₂;
(iii) performing a chemical vapor deposition (CVD) of tungsten;
(iv) performing chemical-mechanical planarization (CMP).

13. A method of enhancing performance of a semiconductor node, comprising:
modifying a design of the semiconductor node, according to a three-dimensional architecture, to form a modified semiconductor node;
fabricating the modified semiconductor node on substrate, along with at least one other node of a different node type.

14. The method of claim 13, wherein the semiconductor node comprises a MOSFET, and the at least one other different node type comprises at least one of JFET and BJT.

15. A method of enhancing performance of semiconductor nodes, comprising:
modifying a design of a first semiconductor node, according to a first three-dimensional architecture, to form a first modified semiconductor node;
modifying a design of a second semiconductor node, according to a second three-dimensional architecture, to form a second modified semiconductor node;
fabricating the first modified semiconductor node and the second modified semiconductor node on substrate.

16. The method of claim 4, wherein the first semiconductor node is a JFET, and the second semiconductor node is a MOSFET.
